(19) United States
(12) Patent Application Publication
(10) Pub. No.: US 2026/0089844 A1
(43) Pub. Date: Mar. 26, 2026

(54) ELECTRONIC DEVICE AND MANUFACTURING METHOD FOR ELECTRONIC DEVICE

(71) Applicant: SONY SEMICONDUCTOR SOLUTIONS CORPORATION, Kanagawa (JP)

(72) Inventor: Takushi SHIGETOSHI, Kanagawa (JP)

(73) Assignee: SONY SEMICONDUCTOR SOLUTIONS CORPORATION, Kanagawa (JP)

(21) Appl. No.: 19/110,383

(22) PCT Filed: Jul. 12, 2023
(86) PCT No.: PCT/JP2023/025782

§ 371 Date: Mar. 10, 2025

(30) Foreign Application Priority Data
Sep. 21, 2022 (JP) 2022-149708

(51) Int. Cl. H05K 1/18; H05K 1/11

(52) U.S. Cl. CPC H05K 1/183; H05K 1/115; H05K 1/185; H05K 2201/10015

(57) ABSTRACT

An electronic device includes a substrate, a first through-hole penetrating the substrate, a capacitive element above the substrate, and a first conductor film. A first portion of the first conductor film traverses the substrate along a side wall of the first through-hole and a second portion of the first conductor film is in contact with the capacitive element.

### TECHNICAL FIELD

The present technology relates to an electronic device and a manufacturing method for an electronic device. Particularly, the present technology relates to an electronic device in which a capacitive element is provided and a manufacturing method for the electronic device.

### BACKGROUND ART

In order to absorb a current variation of a load and suppress fluctuation of a power supply voltage and generation of noise, there is a case in which a capacitive element is formed in a semiconductor device, a circuit board, or the like. For example, a semi-conductor device is proposed in which a capacitive element is formed on an insulating film that covers a first principal surface of a wiring substrate, which may comprise a wiring, on which a through electrode is provided (for example, refer to PTL 1). Further, a semiconductor device is proposed in which a capacitive element is formed on an inner circumferential face of a through-hole provided in an insulator substrate (for example, refer to PTL 2).

### CITATION LIST

### Patent Literature

PTL 1: JP-2012-227266 A

PTL 2: JP-2020-141090 A

### SUMMARY

### Technical Problem

However, with the related art described above, since the capacitive element is formed on the inner circumferential face of the through-hole, there is a possibility that an element region may be decreased at a position of the through-hole.

The present technology has been made in view of such a situation as described above, and it is desirable to form a capacitive element connected to a through electrode, while suppressing decrease of an element region.

### Solution to Problem

According to an embodiment of the present disclosure, there is provided an electronic device including a substrate, a first through-hole penetrating the substrate, a capacitive element above the substrate, and a first conductor film. A first portion of the first conductor film traverses the substrate along a side wall of the first through-hole and a second portion of the first conductor film is in contact with the capacitive element. The substrate includes one or both of a semiconductor substrate comprising a semiconductor element and a wiring substrate comprising a wiring. The capacitive element includes an upper electrode, a lower electrode, and a dielectric film between the upper electrode and the lower electrode, the second portion of the first conductor film is in contact with the upper electrode, and the electronic device further includes a second conductor film and a second through-hole penetrating the substrate. A first portion of the second conductor film traverses the substrate along a side wall of the second through-hole and a second portion of the second conductor film is in contact with the lower electrode. The upper electrode and the lower electrode each comprise one or more of TiN, TaN, and WN. The dielectric film comprises one or more of SiO₂, Si₃N₄, HfO₂, Al₂O₃, ZrO₂, and HfAlO. The dielectric film and the lower electrode have plane sizes substantially equivalent to each other, and the upper electrode has a plane size smaller than the plane size of each of the dielectric film and the lower electrode. The electronic device also includes a sealing film on the capacitive element. The sealing film includes one or more of Si₃N₄ and Al₂O₃. A third portion of the second conductor film is separated from the upper electrode by the sealing film. A parasitic capacitance between the substrate and the lower electrode is equal to or less than one-tenth of a capacitance of the capacitive element. The electronic device also includes an insulating film on the capacitive element, and one or more of a wiring and an external connection terminal above the capacitive element with the insulating film interposed therebetween. The electronic device also includes a photosensitive insulating resin film covering an opening of the first through-hole. The substrate includes a trench in which the capacitive element is embedded. The electronic device also includes a cavity provided in the trench. The electronic device also includes an insulating film provided above the cavity. The capacitive element includes capacitive electrodes having polarities different from each other and having side faces opposed to each other. The first conductor film includes a plurality of vias connected to a capacitive electrode of the capacitive element. The capacitive element includes a plurality of capacitive elements having plane sizes different from each other. The capacitive element includes a plurality of upper electrodes above a lower electrode, wherein the plurality of upper electrodes have plane sizes different from each other. The electronic device also includes a via connected to the lower electrode through a gap between the upper electrodes. The first through-hole penetrates the capacitive element. The electronic device also includes a wiring layer on a bottom surface of the substrate and in contact with the first portion of the first conductor film. The bottom surface of the substrate opposes a top surface of the substrate. The electronic device also includes a semi-conductor chip connected to the wiring layer. The semiconductor chip comprises a solid-state imaging device. According to an aspect of the present disclosure, there is provided an electronic device including a substrate, a capacitive element above the substrate, and a through electrode penetrating the substrate and the capacitive element. The through electrode comprises a first portion of a first conductor film and wherein a second portion of the first conductor film is in contact with the capacitive element. According to an aspect of the present disclosure, there is provided an electronic device including a semiconductor substrate, a wiring layer on a front face side of the semi-conductor substrate, a through electrode that penetrates the semiconductor substrate and connects to the wiring layer, a trench in a rear face of the semiconductor substrate, a capacitive element embedded in the trench, and a wiring that connects the through electrode to the capacitive element. The wiring comprises a conductor film, wherein the through electrode comprises a portion of the conductor film. At least a portion of the capacitive element extends along a side wall of the trench and the side wall of the trench comprises a textured surface. The electronic device also includes a cavity in the trench. According to an aspect of the present disclosure, there is provided a method for manufacturing an electronic device, the method includes forming a capacitive element on a substrate, forming a through-hole in the substrate, and forming a through electrode along a side wall of the through-hole. The through electrode is electrically connected to the capacitive element. The through electrode comprises a portion of a conductor film. The through electrode is electrically connected to the capacitive element. The manufacturing method for an electronic device also includes forming an insulating film covering a side wall of the through-hole and the capacitive element and removing the insulating film from a bottom face of the through-hole to form an opening in the insulating film. The manufacturing method for an electronic device also includes forming a sealing film on the capacitive element. The portion of the insulating film is removed by etching the insulating film using the sealing film as an etching stopper.

According to a first mode of the present technology, there is provided an electronic device including a substrate, a through-hole penetrating the substrate, a through electrode formed on a side wall of the through-hole, a capacitive element formed on (or above) the substrate, and a line that is formed by extending a conductor film used for the through electrode (or a portion of a conductor film traverses the substrate along a side wall of the through-hole) and is connected to (or in contact with) the capacitive element. For example, the through electrode may comprise a portion of a conductor film which may traverse the substrate along a side wall of the through-hole. This brings about an advantageous effect that the line connected to the capacitive element and the through electrode are configured from the conductor film of the same layer.

Further, in the first mode, the substrate may include a semiconductor substrate in which a semiconductor element is formed or a wiring substrate in which a line is formed. This brings about an advantageous effect that the through electrode is formed in the substrate on which the capacitive element is formed.

Further, in the first mode, the capacitive element may include an upper electrode, a lower electrode, and a dielectric film positioned between the upper electrode and the lower electrode, the through electrode may include a first through electrode, and a second through electrode, and the line may include a first line that is formed by extending a conductor film used for the first through electrode and is connected to or in contact with the upper electrode, for example a portion of a conductor film may be connected to or in contact with the upper electrode, and a second line that is formed by extending a conductor film used for the second through electrode and is connected to or in contact with the lower electrode, for example a second conductor film may traverse the substrate along a side wall of a second through-hole and be connected to or in contact with the lower electrode. This brings about an advantageous effect that the through electrode is disposed in the proximity of the capacitive element formed on the substrate.

Further, in the first mode, the upper electrode and the lower electrode may each include at least any one of TiN, TaN, and WN. This brings about an advantageous effect that the reliability of the capacitive element is secured.

Further, in the first mode, the dielectric film may include at least any one of SiO₂, Si₃ N₄, HfO₂, Al₂O₃, ZrO₂, and HfAlO. This brings about an advantageous effect that the reliability of the capacitive element is secured.

Further, in the first mode, the dielectric film and the lower electrode may have plane sizes substantially equal to each other, and the upper electrode may have a plane size smaller than the plane sizes of the dielectric film and the lower electrode. This brings about an advantageous effect that a contact with the lower electrode is secured.

Further, in the first mode, the electronic device may further include a sealing film that is formed on the capacitive element and include at least any one of Si₃N₄ and Al₂O₃. This brings about an advantageous effect that the capacitive element is sealed.

Further, in the first mode, the electronic device may further include a capacitive electrode formed on the upper electrode with the sealing film interposed therebetween and configured from the conductor film used for the second line. This brings about advantageous effects that the capacitance of the capacitive element is increased while increase of the plane size of the capacitive element is suppressed and that the line connected to the capacitive element and the through electrode are configured from the conductor film of the same layer.

Further, in the first mode, the electronic device may further include an insulating film formed on the capacitive element, and at least any one of a line (or wiring) and an external connection terminal formed above the capacitive element with the insulating film interposed therebetween. This brings about an advantageous effect that the line and external connection terminal and the capacitive element are disposed in an overlapping relation with each other.

Further, in the first mode, a parasitic capacitance between the substrate and the lower electrode may be equal to or less than 1/10 the capacitance of the capacitive element. This brings about an advantageous effect that noise is suppressed.

Further, in the first mode, the electronic device may further include a photosensitive insulating resin film that covers the through-hole, for example by covering an opening of the through-hole. This brings about an advantageous effect that a void (or a recess or cavity) is formed in the through-hole while patterning of the photosensitive insulating resin film is simplified.

Further, in the first mode, the substrate may further include a trench in which the capacitive element is formed (or embedded). This brings about an advantageous effect that the capacitance of the capacitive element formed on the substrate is increased while decrease of the element region is suppressed.

Further, in the first mode, the electronic device may further include a void provided in the trench. This brings about an advantageous effect that warping of the substrate arising from the capacitive element formed in the trench is prevented.

Further, in the first mode, the electronic device may further include an insulating film provided on (or above) the void. This brings about an advantageous effect that the capacitive element in the trench in which the void is provided is sealed.

Further, in the first mode, the capacitive element may include capacitive electrodes having polarities different from each other and having side faces opposed to each other. This brings about an advantageous effect that the capacitance of the capacitive element is increased while increase of the plane size is suppressed.

Further, in the first mode, the line may include a plurality of vias connected to a capacitive electrode of the capacitive element. This brings about an advantageous effect that a potential of the capacitive element is stabilized.

Further, in the first mode, the capacitive element may include a plurality of capacitive elements having plane sizes different from each other. This brings about an advantageous effect that the capacitive elements having characteristics different from each other are formed on the substrate.

Further, in the first mode, the capacitive element may include a plurality of upper electrodes that are disposed on the lower electrode and have plane sizes different from each other. This brings about an advantageous effect that the capacitive elements having characteristics different from each other are formed without separating the lower electrode.

Further, in the first mode, the electronic device may further include a via connected to the lower electrode through a gap between the upper electrodes. This brings about an advantageous effect that a potential of the lower electrode is stabilized while the capacitive elements having characteristics different from each other are formed.

Further, in the first mode, the through electrode may penetrate the capacitive element. This brings about an advantageous effect that a space necessary to dispose the through electrode outside the capacitive element is reduced.

Further, in the first mode, the electronic device may further include a wiring layer that is formed on a face (such as a bottom surface, the bottom surface opposing a top surface of the substrate) of the substrate on an opposite side to a formation face of the capacitive element and is connected to or in contact with the through electrode (such as a portion of a conductor film), and a semiconductor chip connected to the wiring layer and having a solid-state imaging device formed therein. This brings about an advantageous effect that operation of the packaged solid-state imaging element is stabilized.

Meanwhile, according to a second mode, an electronic device may include a substrate, a capacitive element formed on (or above) the substrate, and a through electrode penetrating the substrate and the capacitive element. This brings about an advantageous effect that the space necessary to dispose the through electrode outside the capacitive element is reduced.

Further, in the second mode, the electronic device may further include a line that is formed by extending a conductor film used for the through electrode and is connected to the capacitive element. This brings about an advantageous effect that the line connected to the capacitive element and the through electrode are configured from the conductor film of the same layer.

Further, in a third mode, an electronic device may include a semiconductor substrate, a wiring layer formed on a front face side of the semiconductor substrate, a through electrode (or through-hole) that penetrates the semiconductor substrate and is connected to the wiring layer, a trench formed on a rear face side (or in a rear face) of the semiconductor substrate, a capacitive element formed in the trench, and a line that connects the through electrode and the capacitive element to each other. This brings about an advantageous effect that the capacitance of the capacitive element formed on the substrate is increased while decrease of the element region is suppressed.

Further, in the third mode, the line may be configured by extending a conductor film used for the through electrode. This brings about an advantageous effect that the line connected to the capacitive element and the through electrode are configured from the conductor film of the same layer.

Further, in the third mode, the capacitive element may be formed (or may extend) along a side wall of the trench, and the trench may have an irregular (or textured) surface formed on the side wall thereof. This brings about an advantageous effect that the capacitance of the capacitive element formed on the substrate is increased while increase of a depth of the trench is suppressed.

Further, in the third mode, the electronic device may further include a void provided in the trench. This brings about an advantageous effect that warping of the substrate arising from the capacitive element formed in the trench is prevented.

Further, in a fourth mode, a manufacturing method for (or a method for manufacturing) an electronic device may include forming a capacitive element on a substrate, forming a through-hole in the substrate on which the capacitive element is formed, and forming a through electrode (such as along a side wall of the through-hole) which is electrically connected to the capacitive element, on a side wall of the through-hole. This brings about an advantageous effect that the capacitive element is formed on a substrate while the capacitive element is prevented from being formed in the through-hole.

Further, in the fourth mode, a conductor film used for the through electrode may be extended and electrically connected to the capacitive element. For example, the through electrode may comprise a portion of a conductor film and a portion of the conductor film may be electrically connected to or in contact with the capacitive element. This brings about an advantageous effect that the line connected to the capacitive element and the through electrode are formed by the same process.

Further, in the fourth mode, the manufacturing method may further include forming an insulating film that covers a side wall of the through-hole and the capacitive element and removing the insulating film from a bottom face of the through-hole and forming an opening in the insulating film on the capacitive element. This brings about an advantageous effect that the same insulating film is used for the insulation of the through electrode and the substrate and the insulation of the line connected to the capacitive element.

Further, in the fourth mode, the manufacturing method may further include forming a sealing film on the capacitive element formed on the substrate, and the sealing film may be used as an etching stopper when the opening is formed in the insulating film on the capacitive element. For example, a portion of the insulating film may be removed by etching the insulating film using the sealing film as an etching stopper. This brings about an advantageous effect that an opening is formed in the insulating film on the capacitive element while over-etching is suppressed.

### BRIEF DESCRIPTION OF DRAWINGS

FIG. 1 is a cross sectional view depicting an example of a configuration of a semiconductor device according a first embodiment.

FIG. 2 is a first cross sectional view depicting an example of a manufacturing method for the semiconductor device according to the first embodiment.

FIG. 3 is a second cross sectional view depicting the example of the manufacturing method for the semiconductor device according to the first embodiment.

FIG. 4 is a third cross-sectional view depicting the example of the manufacturing method for the semiconductor device according to the first embodiment.

FIG. 5 is a fourth cross sectional view depicting the example of the manufacturing method for the semiconductor device according to the first embodiment.

FIG. 6 is a fifth cross sectional view depicting the example of the manufacturing method for the semiconductor device according to the first embodiment.

FIG. 7 is a sixth cross sectional view depicting the example of the manufacturing method for the semiconductor device according to the first embodiment.

FIG. 8 is a seventh cross sectional view depicting an example of the manufacturing method for the semiconductor device according to the first embodiment.

FIG. 9 is an eighth cross sectional view depicting the example of the manufacturing method for the semiconductor device according to the first embodiment.

FIG. 10 is a top plan view depicting an example of a configuration of a semi-conductor device according to a second embodiment.

FIG. 11 is a cross sectional view depicting an example of a configuration of a semiconductor device according to a third embodiment.

FIG. 12 is a top plan view depicting the example of the configuration of the semiconductor device according to the third embodiment.

FIG. 13 is a cross sectional view depicting an example of a configuration of a capacitive element according to a fourth embodiment.

FIG. 14 is a cross sectional view depicting an example of a configuration of a semiconductor device according to a fifth embodiment.

FIG. 15 is a cross sectional view depicting an example of a configuration of a semiconductor device according to a sixth embodiment.

FIG. 16 is a cross sectional view depicting an example of a configuration of a semiconductor device according to a seventh embodiment.

FIG. 17 is a cross sectional view depicting an example of a configuration of a semiconductor device according to an eighth embodiment.

FIG. 18 is a cross sectional view depicting an example of a configuration of a semiconductor device according to a ninth embodiment.

FIG. 19 depicts top plan views, each depicting an example of a configuration of a capacitive element according to a tenth embodiment.

FIG. 20 is a cross sectional view depicting an example of a configuration of a semiconductor device according to an eleventh embodiment.

FIG. 21 is a block diagram depicting an example of a schematic configuration of a vehicle control system.

FIG. 22 is an explanatory view depicting an example of an installation position of an imaging section.

### DESCRIPTION OF EMBODIMENTS

In the following, modes for carrying out the present technology (hereinafter referred to as embodiments) are described. The description is given according to the following order.
1. First Embodiment (an example in which a capacitive element provided on a semi-conductor substrate and a through electrode provided in the semiconductor substrate are connected to each other through a line configured by extending a conductor film used for the through electrode)
2. Second Embodiment (an example in which a line and a bump electrode connected to a through electrode provided in a semiconductor substrate are formed on a capacitive element provided on the semiconductor substrate)
3. Third Embodiment (an example in which a through electrode penetrating a capacitive element provided on a semiconductor substrate is connected to the capacitive element through the semiconductor substrate)
4. Fourth Embodiment (an example in which a plurality of upper electrodes is provided on one lower electrode and a plurality of vias is connected to each of the lower electrode and the upper electrodes)
5. Fifth Embodiment (an example in which a capacitive element and a through electrode that is provided in a semiconductor substrate are connected to each other through a line configured by extending a conductor film used for the through electrode and the line is used also as the capacitive electrode)
6. Sixth Embodiment (an example in which a capacitive element is formed along an irregular surface of a side wall of a trench formed on a rear face side of a semi-conductor substrate in which a through electrode is provided)
7. Seventh Embodiment (an example in which a capacitive element is formed along a side wall of a trench formed on a rear face side of a semiconductor substrate in which a through electrode is provided and a void is provided in the trench and besides an insulating film that covers the capacitive element is formed on the void)
8. Eighth Embodiment (an example in which a capacitive element is formed along a side wall of a trench formed on a rear face side of a semiconductor substrate in which a through electrode is provided and a void is provided in the trench and besides a sealing film that seals the capacitive element is formed on the void)
9. Ninth Embodiment (an example in which a lower electrode provided on a rear face side of a semiconductor substrate is patterned such that the lower electrode and an upper electrode also provided on the rear face side of the semiconductor substrate have side faces opposed to each other)
10. Tenth Embodiment (an example in which a lower electrode provided on a rear face side of a semiconductor substrate is patterned so as to have opposed side faces and an upper electrode provided on the lower electrode is patterned so as to have opposed side faces)
11. Eleventh Embodiment (an example in which a semiconductor chip in which a solid-state imaging element is formed is stacked on a semiconductor substrate in which a capacitive element connected to a through electrode is formed)

### 1. First Embodiment

In the following description, a semiconductor device in which a through electrode and a capacitive element are provided is taken as an example of an electronic device. The present technology may also be applied to a circuit board in which a through electrode and a capacitive element are provided and may also be applied to a semi-conductor package in which a through electrode and a capacitive element are provided.

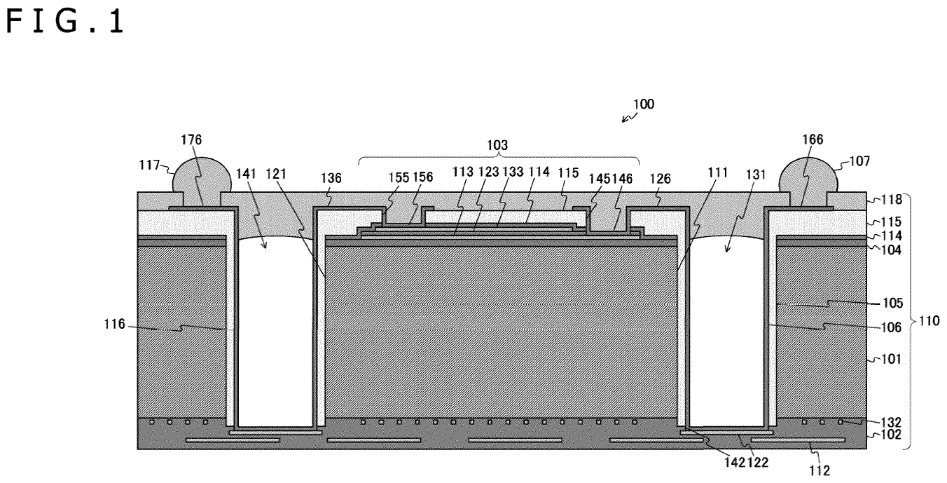

FIG. 1 is a cross sectional view depicting an example of a configuration of a semi-conductor device according to the first embodiment.

Referring to FIG. 1, the semiconductor device 100 includes a semiconductor chip 110. The semiconductor chip 110 has a semiconductor element formed therein. The semiconductor chip 110 may have formed therein a semiconductor memory such as a static random-access memory (SRAM) or a dynamic random-access memory (DRAM). Further, the semiconductor device 100 may have formed therein a processor such as a central processing unit (CPU) or a graphics processing unit (GPU). Further, the semiconductor device 100 may have formed therein a hardware circuit such as a field-programmable gate array (FPGA) or an application specific integrated circuit (ASIC). The semiconductor chip 110 may have a signal processing circuit formed therein, may have a data processing circuit formed therein, may have an interface circuit formed therein or may have an optical element formed therein.

The semiconductor chip 110 includes a semiconductor substrate 101. A semi-conductor element such as a transistor or a diode can be formed on a front face side of the semiconductor substrate 101. The semiconductor elements may be integrated. For a material of the semiconductor substrate 101, a semiconductor such as Si, SiC, GaN, GaAs, or InGaAsP can be used.

On the semiconductor substrate 101 on which semiconductor elements are formed, a gate electrode 132 is formed, and a wiring layer 102 is formed in such a manner as to cover the gate electrode 132. A pad electrode 122 and a line 112 (or conductor film) are formed in the wiring layer 102. The gate electrode 132, the pad electrode 122, and the line 112 are embedded in an insulating film that insulates the wiring layer 102. Further, the wiring layer 102 has formed therein an opening 142 that exposes the pad electrode 122 on a rear face side of the semiconductor substrate 101.

For a material of the gate electrode 132, for example, polycrystalline silicon, silicide, and the like can be used. For materials of the pad electrode 122 and the line 112, for example, a metal such as Cu or Al can be used.

On the rear face side of the semiconductor substrate 101, a capacitive element 103 is formed with a rear face insulating film 104 interposed therebetween. The capacitive element 103 may in some embodiments be set on or embedded in the semiconductor substrate 101. The capacitive element 103 includes a lower electrode 113, a dielectric film 123, and an upper electrode 133. The lower electrode 113 is formed on the rear face insulating film 104, and the upper electrode 133 is formed on the lower electrode 113 with the dielectric film 123 interposed therebetween. Plane sizes of the dielectric film 123 and the lower electrode 113 can be made substantially equal (or equivalent) to each other. Substantially equal may be equal or may be a displacement within approximately several percent. By making the plane sizes of the dielectric film 123 and the lower electrode 113 substantially equal to each other, a distance between the upper electrode 133 and the lower electrode 113 can be increased, and reliability can be improved. A plane size of the upper electrode 133 can be made smaller than the plane sizes of the dielectric film 123 and the lower electrode 113. Here, by making the plane size of the upper electrode 133 smaller than the plane sizes of the dielectric film 123 and the lower electrode 113, a contact region with the lower electrode 113 can be secured.

For a material of the rear face insulating film 104, for example, an inorganic material such as SiO₂, SiON, SiOC, Si₃N₄, or SiCO, an organic material such as polyimide, acrylic, silicone or a material with an epoxy group skeleton, or a layered structure of a plurality of materials may be adopted. A film thickness of the rear face insulating film 104 can be set such that a parasitic capacitance between the semiconductor substrate 101 and the lower electrode 113 is made equal to or lower than one tenth a capacitance of the capacitive element 103, and may be made equal to or lower than one twentieth the capacitance of the capacitive element 103. By setting the parasitic capacitance between the semiconductor substrate 101 and the lower electrode 113 to one tenth or less the capacitance of the capacitive element 103, the noise suppression effect can be improved.

For materials of the upper electrode 133 and the lower electrode 113, for example, TiN, TaN, WN, W, Al, Ti, Ta, Cu, Ru, and Co can be used, and a layered structure of a plurality of materials may be adopted. In some implementations, the materials of the upper electrode 133 and the lower electrode 113 may include at least any one of TiN, TaN and WN. For a material of the dielectric film 123, for example, SiO₂, SiON, Si₃N₄, hafnium oxide (HfO₂), aluminum oxide (Al₂O₃), zirconium oxide (ZrO), tantalum oxide (Ta₂O₅), titanium oxide (TiO₂), lanthanum oxide (LaO₃), yttrium oxide (Y₂O₃), aluminum nitride (AlN), hafnium oxynitride (HfON), and aluminum oxynitride (AlON) can be used, and a layered structure of a plurality of materials may be adopted. In some implementations, the material of the dielectric film 123 includes at least any one of SiO₂, Si₃N₄, HfO₂, Al₂O₃, ZrO₂, and HfAlO. By using the above-described materials to configure the capacitive element 103, the reliability of the capacitive element 103 can be secured.

On the rear face insulating film 104, a sealing film 114 is formed in such a manner as to cover the capacitive element 103. For a material of the sealing film 114, for example, SiO₂, SiON, Si₃N₄, SiCN, SiC, Al₂O₃, and HfO₂ can be used, and a layered structure of a plurality of materials may be adopted. In some implementations, the material of the sealing film 114 includes at least any one of Si₃N₄ and Al₂O₃. By forming the sealing film 114 on the capacitive element 103, humidity resistance and dust resistance of the capacitive element 103 can be improved, and the reliability of the capacitive element 103 formed on the rear face side of the semiconductor substrate 101 can be improved.

In the semiconductor substrate 101, through-holes 111 and 121 are formed. At this time, the through-holes 111 and 121 can penetrate the rear face insulating film 104 and the sealing film 114 together with the semiconductor substrate 101 and enter into the wiring layer 102. The through-holes 111 and 121 can each be disposed in the proximity of the capacitive element 103 and may be disposed adjacent to the capacitive element 103. Each bottom face of the through-holes 111 and 121 is disposed at a position opposed to the pad electrode 122. An aspect ratio of each of the through-holes 111 and 121 can be set within a range from 1 to 10.

An insulating film 105 is formed on a side wall of each of the through-holes 111 and 121, and an insulating film 115 is formed on the sealing film 114 in such a manner as to cover the capacitive element 103. The insulating films 105 and 115 may be formed continuously from the same material. The insulating films 105 and 115 may be different from each other in film thickness or may be different from each other in film configuration. For materials of the insulating films 105 and 115, for example, an inorganic material such as SiO₂, SiON, SiOC, Si₃N₄, or SiCO or an organic material such as polyimide, acrylic, silicone, or a material with an epoxy group skeleton or a layered structure of a plurality of materials may be adopted.

The insulating film 115, the sealing film 114, and the dielectric film 123 have an opening 145 formed therein such that the opening 145 exposes the lower electrode 113 therethrough. Further, the insulating film 115 and the sealing film 114 have an opening 155 formed therein such that the opening 155 exposes the upper electrode 133 therethrough.

Through electrodes 106 and 116 are formed on side walls of the through-holes 111 and 121, respectively, with the insulating film 105 interposed therebetween. At this time, voids 131 and 141 may be formed in the through-holes 111 and 121 in which the through electrodes 106 and 116 are formed, respectively.

A conductor film used for each of the through electrodes 106 and 116 is extended and connected to the capacitive element 103. At this time, the conductor film used for each of the through electrodes 106 and 116 can be extended onto the insulating film 115 so as to cover the openings 145 and 155, respectively. Here, rear face lines 126, 136, 166, and 176 and vias 146 and 156 can include the conductor film used for each of the through electrodes 106 and 116. The via 146 can be provided in the rear face line 126. The via 156 can be provided in the rear face line 136. At this time, the through electrodes 106 and 116, the rear face lines 126, 136, 166, and 176 and the vias 146 and 156 can include a conductor film in one layer. The via 146 is connected to the lower electrode 113 through the opening 145, and the via 156 is connected to the upper electrode 133 through the opening 155. Further, the through electrode 106 is connected to the via 146 by the rear face line 126 and is connected to a bump electrode 107 by the rear face line 166. The through electrode 116 is connected to the via 156 by the rear face line 136 and is connected to a bump electrode 117 by the rear face line 176. For a material of the through electrodes 106 and 116, the rear face lines 126, 136, 166, and 176, and the vias 146 and 156, for example, Cu, Ti, Ta, Al, W, Ni, Ru, Co, TiN, TaN, and WN can be used, or a layered structure of a plurality of materials may be adopted. A distance between the via 146 and the upper electrode 133 may be set to 0.2 μm or more. A distance between each of the through electrodes 106 and 116 and the lower electrode 113 may be set to 0.2 μm or more.

A protective film 118 is formed on the insulating film 115. At this time, the protective film 118 can be positioned on the voids 131 and 141. For a material of the protective film 118, an organic material such as polyimide, acrylic, silicone, or a material with an epoxy group skeleton, or a material containing a filler such as SiO₂, Al₂O₃, AlN, or BN can be used. In order to form the protective film 118 on the voids 131 and 141 such that it is not filled in the voids 131 and 141, a coated film may be used. The coated film may be a photosensitive insulating resin film.

The bump electrodes 107 and 117 are formed on the protective film 118. The bump electrodes 107 and 117 are connected to the rear face lines 166 and 176 through the protective film 118, respectively. At this time, the protective film 118 can have an opening formed therein such that it exposes part of each of the rear face lines 166 and 176 therethrough at the position of each of the bump electrodes 107 and 117. The rear face lines 166 and 176 may have provided thereon pad electrodes to which the bump electrodes 107 and 117 are connected, respectively. Each of the bump electrodes 107 and 117 may be a solder ball or may be a pillar electrode. It is to be noted that each of the bump electrodes 107 and 117 is an example of an external connection terminal described in the claims.

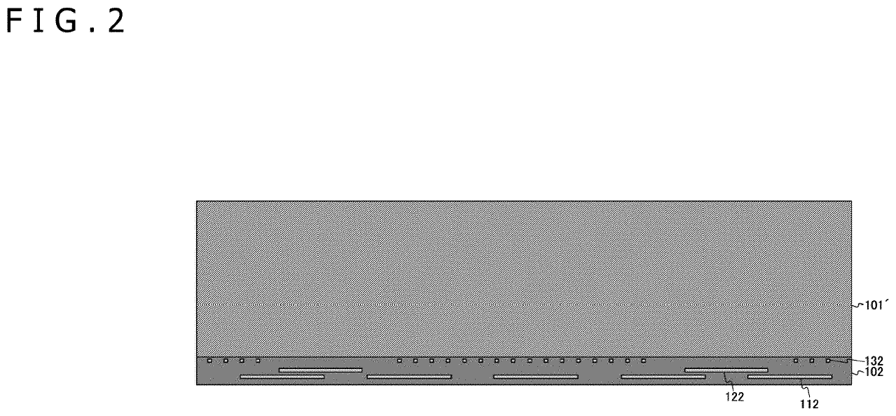

FIGS. 2 to 9 are cross sectional views depicting an example of a manufacturing method for the semiconductor device according to the first embodiment.

Referring to FIG. 2, a semiconductor element is formed on a front face side of a semiconductor wafer 101′. It is to be noted that the semiconductor wafer 101′ can be partitioned for each semiconductor chip 110. A dicing line can be provided on a boundary between partitioned regions of the semiconductor chip 110.

In a case where a metal oxide semiconductor (MOS) transistor is formed as the semi-conductor element, an impurity diffusion layer and an element separation layer may be formed in the semiconductor wafer 101′, and a gate electrode 132 may be formed on the semiconductor wafer 101′. Further, a wiring layer 102 is formed on the semi-conductor wafer 101′ so as to cover the gate electrode 132. A pad electrode 122 and a line 112 embedded in an insulating film can be formed in the wiring layer 102. It is to be noted that the semiconductor wafer 101′ may be thinned to a desired thickness from a rear face side of the semiconductor wafer 101′ by a method such as chemical mechanical polishing (CMP).

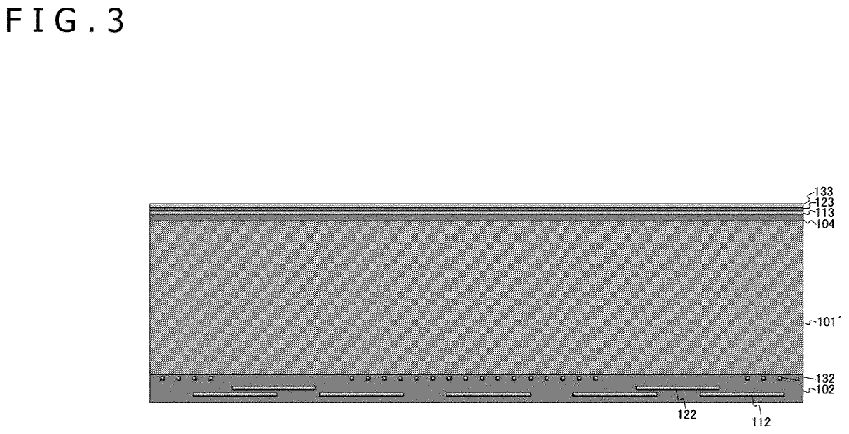

Then, a rear face insulating film 104 is formed on the rear face side of the semi-conductor wafer 101′ by such a method as plasma enhanced-chemical vapor deposition (PE-CVD) as depicted in FIG. 3. Then, a lower electrode 113, a dielectric film 123, and an upper electrode 133 are formed sequentially on the rear face insulating film 104. For the film formation of the electrodes such as the lower electrode 113 and the upper electrode 133, PE-CVD, plasma enhanced-physical vapor deposition (PE-PVD), metal organic-chemical vapor deposition (MO-CVD), or atomic layer deposition (ALD) can be used. For the film formation of the dielectric film 123, PE-CVD or ALD can be used.

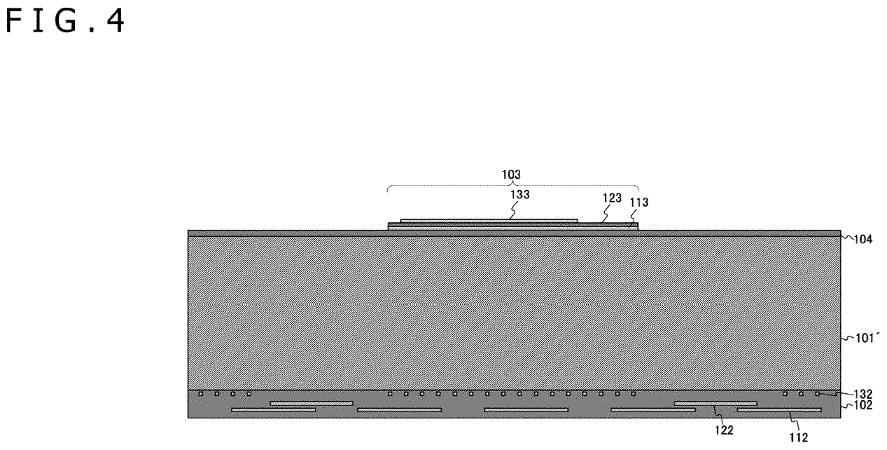

Then, as depicted in FIG. 4, the lower electrode 113 and the dielectric film 123 are patterned by lithography or dry etching, and then, the upper electrode 133 is patterned to form a capacitive element 103 on the rear face insulating film 104. In the etching of the upper electrode 133, a selectivity can be set such that the dielectric film 123 remains on the lower electrode 113. At this time, as etching gas, for example, Cl₂ or HBr gas may be used. If the patterns are not fine patterns, then patterning may be performed by wet etching. A hard mask may be formed on the upper electrode 133.

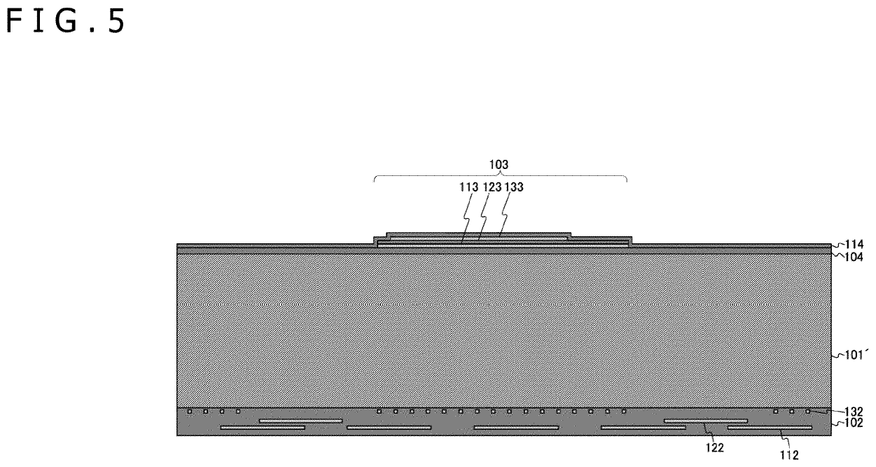

Then, as depicted in FIG. 5, a sealing film 114 is formed on the rear face insulating film 104 by such a method as PE-CVD or ALD so as to cover the capacitive element 103.

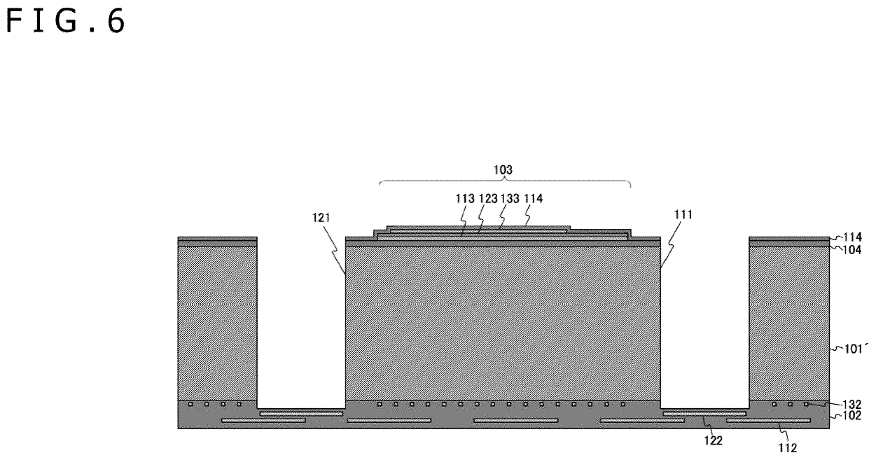

Then, as depicted in FIG. 6, the sealing film 114, the rear face insulating film 104, and the semiconductor wafer 101′ are patterned by lithography and dry etching to form through-holes 111 and 121 in the sealing film 114, the rear face insulating film 104, and the semiconductor wafer 101′. The through-holes 111 and 121 can each be disposed in the proximity of the capacitive element 103.

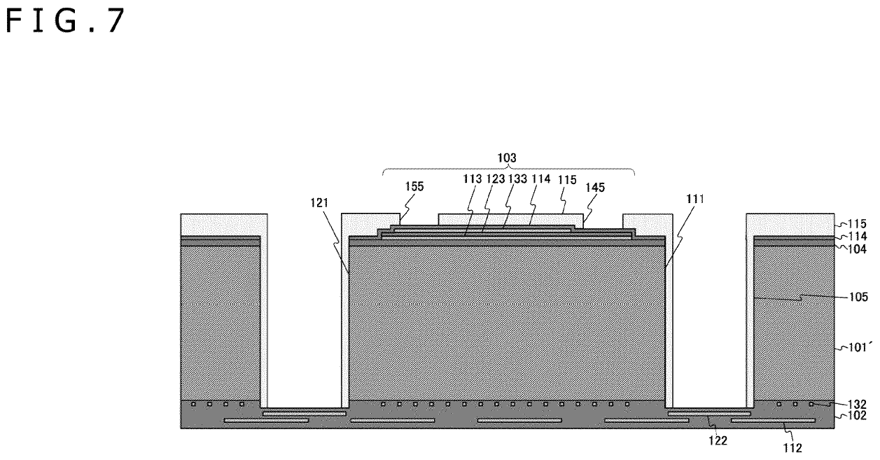

Then, as depicted in FIG. 7, an insulating film 105 is formed on a side wall of each of the through-holes 111 and 121, and an insulating film 115 is formed on the sealing film 114. The insulating films 105 and 115 may be formed by the same film formation method. Then, the insulating films 105 and 115 are patterned to remove the insulating film 105 on the bottom face of each of the through-holes 111 and 121 and form openings 145 and 155 in the insulating film 115. At this time, a photosensitive insulating resin film may be formed as the insulating films 105 and 115 by coating or layering, whereafter it is patterned by lithography. Alternatively, after the insulating films 105 and 115 are formed on an overall area of the rear face side of the semi-conductor wafer 101′ by PE-CVD, they may be patterned by lithography and dry etching. Here, materials different from each other may be used for the sealing film 114 and the insulating film 115. At this time, an etching rate for the sealing film 114 may be made lower than an etching rate for the insulating film 115 such that the sealing film 114 is used as an etching stopper. This makes it possible to suppress a characteristic variation by excessive over-etching to semiconductor elements on the front face side of the semiconductor wafer 101′ and the capacitive element 103 on the rear face side of the semiconductor wafer 101′. The material of the sealing film 114 and the material of the insulating film 115 when the sealing film 114 is used as the etching stopper may be a combination of, for example, SiO₂ and Si₃N₄ or may be a combination of an inorganic film and an organic film.

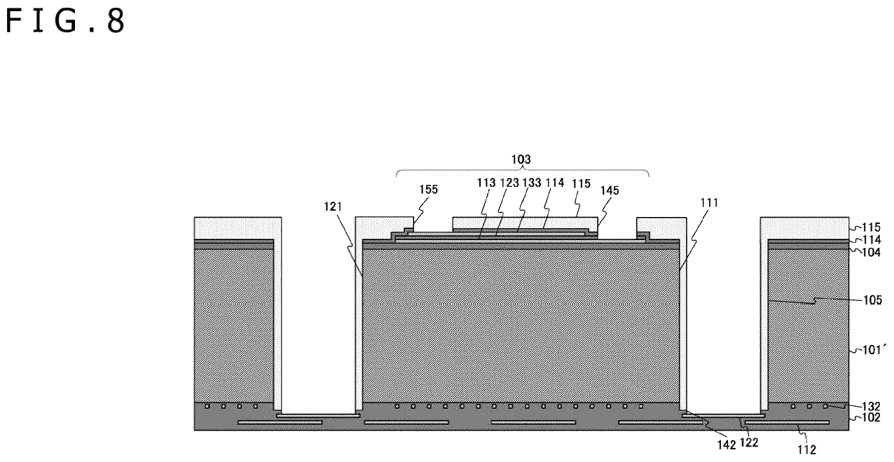

Then, as depicted in FIG. 8, the wiring layer 102 is patterned through the through-holes 111 and 121 by dry etching to form an opening 142 that exposes the pad electrode 122 therethrough. At this time, the sealing film 114 and the dielectric film 123 are patterned through the opening 145 to expose the lower electrode 113 therethrough, and the sealing film 114 is patterned through the opening 155 to expose the upper electrode 133 therethrough. The patterning of the wiring layer 102, the sealing film 114, and the dielectric film 123 can be performed in self-alignment through the through-holes 111 and 121 and the openings 145 and 155.

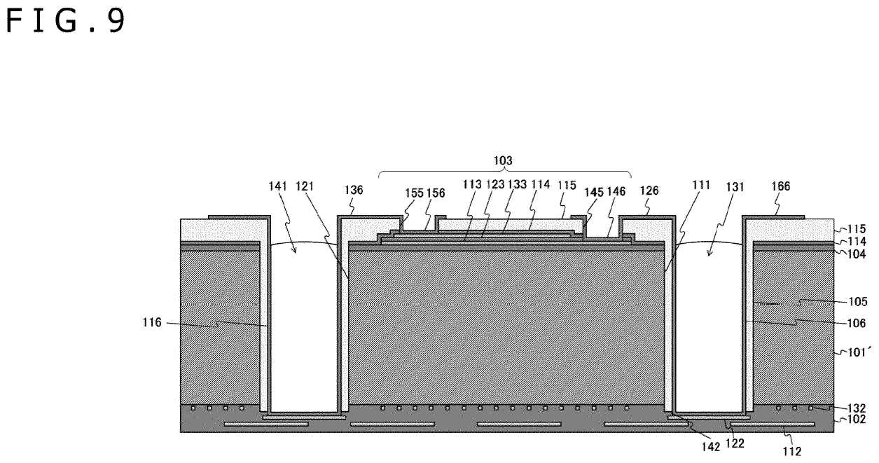

Then, as depicted in FIG. 9, through electrodes 106 and 116, rear face lines 126, 136, 166, and 176, and vias 146 and 156 are formed collectively, for example, by a semi-additive method or the like. As an example of the semi-active method, after a barrier metal film and a seed metal film are formed, a resist pattern is formed by a lithography method. In this resist pattern, a hollow pattern can be formed at each of formation positions of the through electrodes 106 and 116, the rear face lines 126, 136, 166, and 176, and the vias 146 and 156. Then, the through electrodes 106 and 116, the rear face lines 126, 136, 166, and 176, and the vias 146 and 156 can be formed collectively through the resist patterns by electroplating. Thereafter, the resist pattern is removed, and the barrier metal film and the seed metal film are removed by etching back the whole surface of these films.

Then, a protective film 118 is formed on the insulating film 115 as depicted in FIG. 1. At this time, by adjusting the embeddability of the protective film 118 into the through-holes 111 and 121, it is possible to form voids 131 and 141 in the through-holes 111 and 121, respectively. In order to adjust the embeddability of the protective film 118 into the through-holes 111 and 121, a coated film may be used as the protective film 118. At this time, by adjusting the viscosity of the coated film, it is possible to adjust the embeddability of the protective film 118 into the through-holes 111 and 121. Then, openings for allowing the bump electrodes 107 and 117 to be connected to the rear face lines 166 and 176 therethrough, respectively, are formed in the protective film 118. At this time, as the protective film 118, a photosensitive insulating resin may be patterned by lithography after it is formed by coating or layering. Then, the bump electrodes 107 and 117 are connected to the rear face lines 166 and 176, respectively, through the openings formed in the protective film 118. Thereafter, the semiconductor wafer 101′ is cut by such a method as blade cutting to divide the semiconductor wafer 101′ into individual semiconductor chips 110.

In this manner, in the first embodiment described above, the through electrodes 106 and 116, the rear face lines 126, 136, 166, and 176, and the vias 146, 156 are formed from a conductor film in one layer. Consequently, a contact for connecting the through electrode 106 and the via 146 and a contact for connecting the through electrode 116 and the via 156 can be made unnecessary, and it becomes possible to reduce a line resistance, simplifying the manufacturing process, so that the reliability can be enhanced.

Further, the insulating film 105 on the side wall of each of the through-holes 111 and 121 and the insulating film 115 on the capacitive element 103 are formed continuously from the same material, and the through electrodes 106 and 116 are formed on the insulating film 105 and the rear face lines 126 and 136 are formed on the insulating film 115. Consequently, a line length of each of the rear face lines 126 and 136 can be reduced, and the line resistance can be reduced.

Further, a capacitive element 103 is formed on the rear face side of the semi-conductor substrate 101. Accordingly, reduction of an element formation region on the front face side of the semiconductor substrate 101 becomes unnecessary, and it is possible to dispose the capacitive element 103 in the proximity of each of the through electrodes 106 and 116. Therefore, fluctuation of the power supply voltage and generation of noise can be suppressed without involving increase of the chip size.

It is to be noted that the first embodiment described above indicates an example in which the through electrodes 106 and 116, the rear face lines 126, 136, 166, and 176, and the vias 146 and 156 are formed from a conductor film in one layer. In contrast, the through electrodes 106 and 116, rear face lines 126 and 166, and the via 146 may be formed from a conductor film in one layer, while the rear face lines 136 and 176, and the via 156 are formed from a conductor film in another layer. Alternatively, the through electrodes 106 and 116, the rear face lines 136 and 176, and the via 156 may be formed from a conductor film in one layer, while the rear face lines 126 and 166 and the via 146 are formed from a conductor film in another layer.

Further, while the first embodiment described above indicates an example in which one capacitive element 103 is provided on the rear face side of the semiconductor substrate 101, a plurality of capacitive elements 103 may be provided on the rear face side of the semiconductor substrate 101.

### 2. Second Embodiment

In the first embodiment described hereinabove, the bump electrodes 107 and 117 are disposed outside the capacitive element 103 formed on the rear face side of the semi-conductor substrate 101. In the second embodiment, a bump electrode is disposed on a capacitive element 103 formed on the rear face side of a semiconductor substrate 101, and a line that is not connected to the capacitive element 103 is formed on the capacitive element 103.

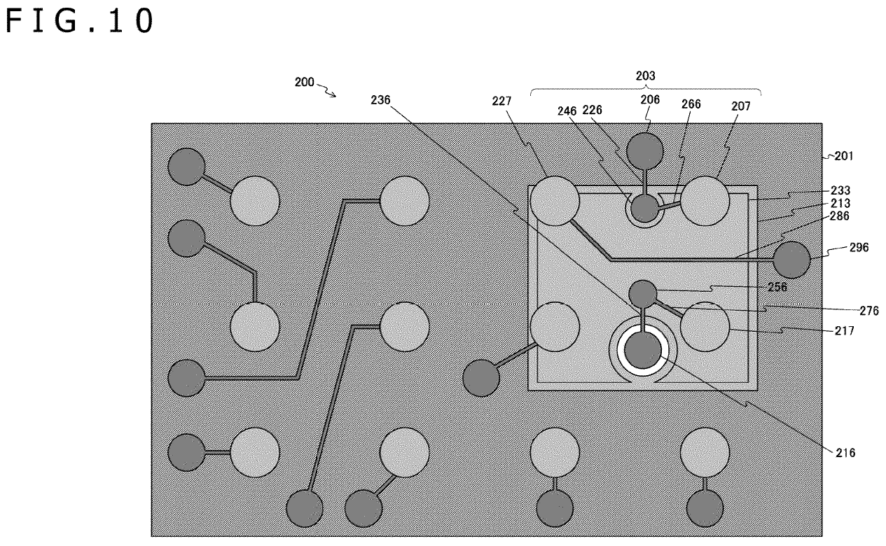

FIG. 10 is a top plan view depicting an example of a configuration of a semi-conductor device according to the second embodiment.

Referring to FIG. 10, the semiconductor device 200 includes a semiconductor substrate 201. The semiconductor substrate 201 has semiconductor elements and a wiring layer formed on the front face side thereof. The semiconductor substrate 201 has formed on the rear face side thereof a capacitive element 203, rear face lines 226, 236, 266, 276, and 286, vias 246 and 256, and bump electrodes 207, 217, and 227. Further, the semiconductor substrate 201 has through electrodes 206, 216 and 296 formed therein.

The capacitive element 203 includes a lower electrode 213 and an upper electrode 233. The lower electrode 213 is formed on the rear face side of the semiconductor substrate 201 with a rear face insulating film interposed therebetween, and the upper electrode 233 is formed on the lower electrode 213 with a dielectric film interposed therebetween.

At least part of each of the bump electrodes 207 and 217 may be formed on the capacitive element 203. The through electrodes 206, 216, and 296 may be disposed anywhere on the semiconductor substrate 201. For example, the through electrode 216 may penetrate the capacitive element 203 with the semiconductor substrate 201 interposed therebetween. At this time, the lower electrode 213 and the upper electrode 233 can be disposed to be spaced apart from the through electrode 216 in such a way as to surround the through electrode 216. This reduces the distance between the capacitive element 203 and the through electrode 216, so that the line resistance can be reduced.

The conductor film used for each of the through electrodes 206 and 216 is extended and connected to the capacitive element 203. At this time, the rear face lines 226, 236, 266, and 276 and the vias 246 and 256 can be configured from the conductor film used for each of the through electrodes 206 and 216. The via 246 is connected to the lower electrode 213, and the via 256 is connected to the upper electrode 233. The via 246 is disposed on the exposed face of the lower electrode 213. the via 246 may be disposed in plural number on the exposed face of the lower electrode 213. The via 256 may be disposed anywhere on the upper electrode 233. The via 256 may be disposed in plural number on the upper electrode 233.

The through electrode 206 is connected to the via 246 through the rear face line 226 and is connected to the bump electrode 207 through the rear face line 266. The through electrode 216 is connected to the via 256 through the rear face line 236 and is connected to the bump electrode 217 through the rear face line 276. The through electrode 296 is connected to the bump electrode 227 through the rear face line 286. The rear face line 286 may extend across the capacitive element 203.

In this manner, in the second embodiment described above, the bump electrodes 207 and 217 are disposed on the capacitive element 103 formed on the rear face side of the semiconductor substrate 101. This makes it possible to reduce the length of the rear face line 266 that connects the bump electrode 207 and the via 246 to each other and reduce the length of the rear face line 276 that connects the bump electrode 217 and the via 256 to each other, so that the line resistance of each of the rear face lines 266 and 276 can be reduced.

Further, the rear face line 286 that connects the bump electrode 227 and the through electrode 296 to each other is disposed on the capacitive element 203. Consequently, it becomes unnecessary to form the rear face line 286 by bypassing the capacitive element 203 in order to connect the bump electrode 227 and the through electrode 296 to each other, which makes it possible to reduce the length of the rear face line 276. Therefore, the line resistance of the rear face line 286 can be reduced.

### 3. Third Embodiment

In the first embodiment described hereinabove, the through electrodes 106 and 116 are each disposed adjacent to the capacitive element 103 formed on the rear face side of the semiconductor substrate 101. In the third embodiment, a through electrode that penetrates a capacitive element through a semiconductor substrate is provided in a semiconductor device.

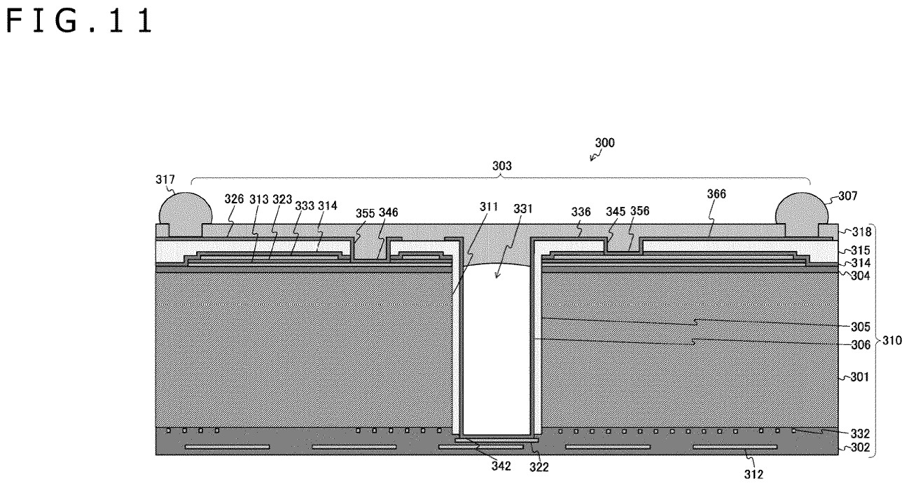

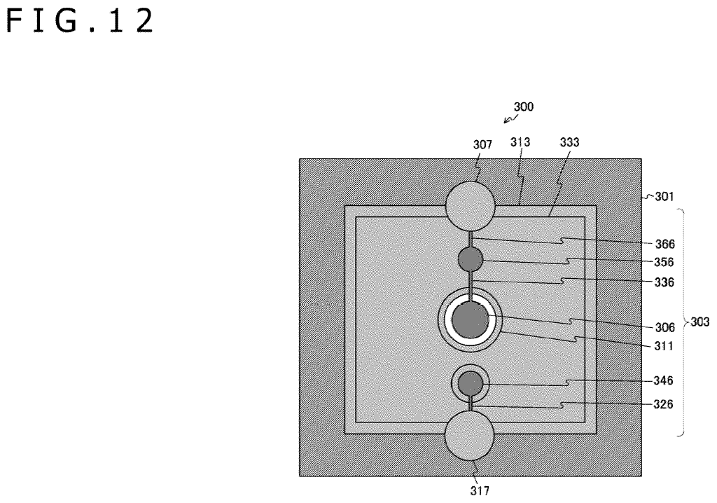

FIG. 11 is a cross sectional view depicting an example of a configuration of a semi-conductor device according to the third embodiment, and FIG. 12 is a top plan view depicting the example of the configuration of the semiconductor device according to the third embodiment.

Referring to FIGS. 11 and 12, a semiconductor device 300 includes a semiconductor chip 310. The semiconductor chip 310 has semiconductor elements formed therein. The semiconductor chip 310 includes a semiconductor substrate 301. On a front face side of the semiconductor substrate 301, a semiconductor element such as a transistor or a diode can be formed.

The semiconductor substrate 301 having the semiconductor elements formed thereon has a gate electrode 332 formed thereon and has a wiring layer 302 formed thereon such that the wiring layer 302 covers the gate electrode 332. The wiring layer 302 has a pad electrode 322 and a line 312 formed therein. Further, the wiring layer 302 has formed therein an opening 342 that exposes the pad electrode 322 therethrough.

The semiconductor substrate 301 has formed on the rear face side thereof a capacitive element 303 with a rear face insulating film 304 interposed therebetween. The capacitive element 303 includes a lower electrode 313, a dielectric film 323, and an upper electrode 333. The lower electrode 313 is formed on the rear face insulating film 304, and the upper electrode 333 is formed on the lower electrode 313 with the dielectric film 323 interposed therebetween. A sealing film 314 formed on the rear face insulating film 304 so as to cover the capacitive element 303.

The semiconductor substrate 301 has a through-hole 311 formed therein. At this time, the through-hole 311 can penetrate the capacitive element 303, the rear face insulating film 304, and the sealing film 314 as well as the semiconductor substrate 301 and enter the wiring layer 302. A bottom face of the through-hole 311 is disposed at a position opposed to the pad electrode 332.

The through-hole 311 has an insulating film 305 formed on a side wall thereof, and the sealing film 314 has an insulating film 315 formed thereon in such a manner as to cover the capacitive element 303. The insulating films 305 and 315 may be formed continuously from the same material.

The insulating film 315, the sealing film 314, and the dielectric film 323 have an opening 345 formed therein such that the opening 345 exposes the lower electrode 313 therethrough. Further, the insulating film 315 and the sealing film 314 have formed therein an opening 355 that exposes the upper electrode 333 therethrough.

The through-hole 311 has formed on a side wall thereof a through electrode 306 with the insulating film 305 interposed therebetween. At this time, the lower electrode 313 and the upper electrode 333 can be disposed to be spaced apart from the through electrode 306 so as to surround the through electrode 306. The through-hole 311 having the through electrode 306 formed therein may have a void 331 formed therein.

The conductor film used for the through electrode 306 is extended and connected to the capacitive element 303. At this time, the conductor film used for the through electrode 306 can be extended on the insulating film 315 in such a manner as to cover the opening 345. Here, rear face lines 326, 336, and 366, and vias 346 and 356 can be configured from the conductor film used for the through electrode 306. At this time, the through electrode 306, the rear face lines 326, 336, and 366, and the vias 346 and 356 can be formed from a conductor film in one layer. The via 346 is connected to the lower electrode 313 through the opening 355, and the via 356 is connected to the upper electrode 333 through the opening 345. Further, the through electrode 306 is connected to the via 356 through the rear face line 336 and is connected to a bump electrode 307 through the rear face line 366. The via 346 is connected to the rear face line 326.

The insulating film 315 has a protective film 318 formed thereon. At this time, the protective film 318 can be positioned on the void 331. The protective film 318 has bump electrodes 307 and 317 formed thereon. The bump electrode 307 is connected to the rear face line 366 with the protective film 318 interposed therebetween. The bump electrode 317 is connected to the rear face line 326 with the protective film 318 interposed therebetween. At this time, the protective film 318 can have an opening formed therein such that the opening exposes part of the rear face line 366 at the position of the bump electrode 307 and can have an opening formed therein such that the opening exposes part of the rear face line 326 at the position of the bump electrode 317.

In this manner, in the third embodiment described above, the through electrode 306 that penetrates the capacitive element 303 through the semiconductor substrate 301 is provided in the semiconductor device 300. This eliminates the necessity to dispose the through electrode 306 outside the capacitive element 303 and makes it possible to reduce a line length of the rear face line 326 that connects the through electrode 306 and the via 346 to each other and further reduce a line length of the rear face line 336 that connects the through electrode 306 and the via 356 to each other. Therefore, it becomes possible to reduce a line resistance of each of the rear face lines 326 and 336, so that fluctuation of the power supply voltage and generation of noise can be reduced.

### 4. Fourth Embodiment

In the first embodiment described hereinabove, the single upper electrode 133 is provided on the single lower electrode 113, the via 146 is connected to the lower electrode 113, and the via 156 is connected to the upper electrode 133. In the fourth embodiment, a plurality of upper electrodes is provided on a single lower electrode, and a plurality of vias is connected to each of the lower electrode and the upper electrodes.

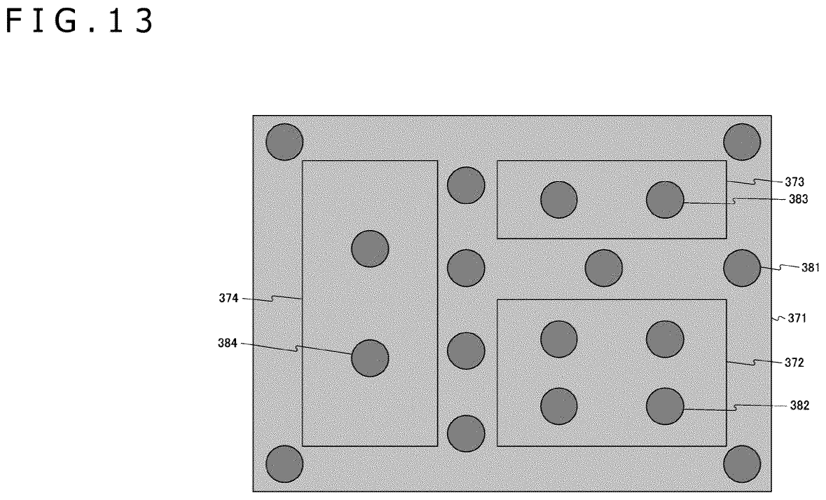

FIG. 13 is a cross sectional view depicting an example of a configuration of a capacitive element according to the fourth embodiment.

Referring to FIG. 13, a capacitive element 370 includes a lower electrode 371, a dielectric film, and upper electrodes 372 to 374. The upper electrodes 372 to 374 are formed on the lower electrode 371 with the dielectric film interposed therebetween. The upper electrodes 372 to 374 may have plane sizes different from each other. A plurality of vias 381 is connected to the lower electrode 371. A plurality of vias 382 is connected to the upper electrode 372. A plurality of vias 383 are connected to the upper electrode 373. A plurality of vias 384 is connected to the upper electrode 374. The vias 381 connected to the lower electrode 371 may be disposed among the upper electrodes 372 to 374.

In this manner, in the fourth embodiment described above, by providing the plurality of upper electrodes 372 to 374 on the single lower electrode 371, the number of the vias 381 to be connected to the lower electrode 371 and the number of lines can be reduced. Further, the lower electrode 371 can be used for blocking of noise and light blocking. Further, by connecting a plurality of vias to each of the lower electrode 371 and the upper electrodes 372 to 374, potentials at the lower electrode 371 and the upper electrodes 372 to 374 can be stabilized. Further, by making the plane sizes of the upper electrodes 372 to 374 different from each other, it is possible to make characteristics such as a cutoff frequency in each electrode different from each other.

### 5. Fifth Embodiment

In the first embodiment described hereinabove, the lower electrode 113 and the upper electrode 133 layered thereon with the dielectric film 123 interposed therebetween are used to form the capacitive element 103 on the rear face side of the semiconductor substrate 101. In the fifth embodiment, a capacitive element and a through electrode are connected to each other by a line configured by extending a conductor film that is used for a through electrode provided on a semiconductor substrate and the line is used also as a capacitive electrode.

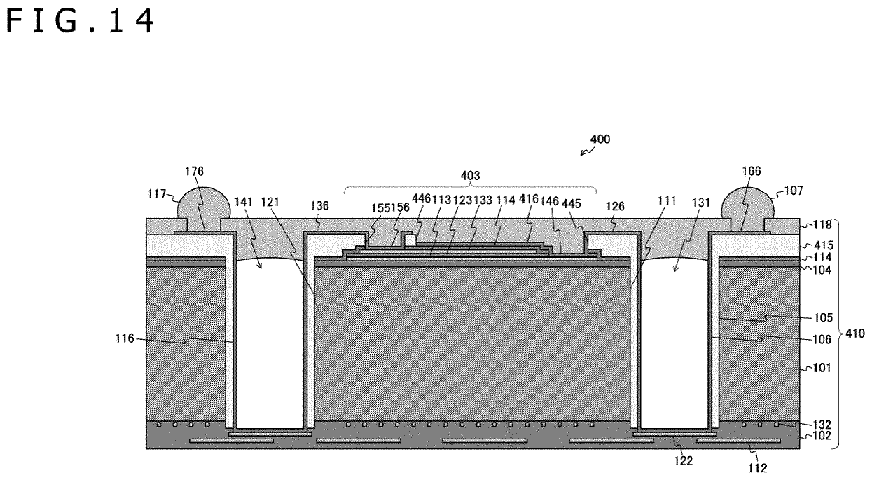

FIG. 14 is a cross sectional view depicting an example of a configuration of a semi-conductor device according to the fifth embodiment.

Referring to FIG. 14, a semiconductor device 400 includes a semiconductor chip 410 in place of the semiconductor chip 110 in the first embodiment described hereinabove. The semiconductor chip 410 includes a capacitive element 403 and an insulating film 415 in place of the capacitive element 103 and the insulating film 105 in the first embodiment described hereinabove. The configuration of the other part of the semi-conductor device 400 of the fifth embodiment is similar to that of the semiconductor device 100 of the first embodiment described hereinabove.

The capacitive element 403 is formed on the rear face side of the semiconductor substrate 101 with the rear face insulating film 104 interposed therebetween. The capacitive element 403 includes a lower electrode 113, a dielectric film 123, an upper electrode 133, a sealing film 114, and a rear face line 416. The lower electrode 113 is formed on the rear face insulating film 104, and the upper electrode 133 is formed on the lower electrode 113 with the dielectric film 123 interposed therebetween. The rear face line 416 is formed on the upper electrode 133 with the sealing film 114 interposed therebetween. The rear face line 416 on the upper electrode 133 can be used as a capacitive electrode. Further, the sealing film 114 between the upper electrode 133 and the rear face line 416 can be used as a dielectric film of the capacitive element 403.

An insulating film 105 is formed on a side wall of each of the through-holes 111 and 121, and an insulating film 415 is formed on the sealing film 114 such that the capacitive element 403 is covered therewith. The insulating films 105 and 415 may be formed continuously from the same material.

The insulating film 415, the sealing film 114, and the dielectric film 123 have an opening 445 formed therein such that the opening 445 exposes the lower electrode 113 therethrough. The insulating film 415 and the sealing film 114 have an opening 155 formed therein such that the opening 155 exposes the upper electrode 133 therethrough. The insulating film 415 has an opening 446 formed therein such that the opening 446 exposes the sealing film 114 on the upper electrode 133 therethrough.

The conductor film used for each of the through electrodes 106 and 116 is extended and connected to the capacitive element 403. At this time, the conductor film used for each of the through electrodes 106 and 116 can be extended onto the insulating film 415 and the sealing film 114 so as to cover the openings 155, 445, and 446. Here, the rear face lines 126, 136, 166, 176, and 416, and the vias 146 and 156 can be configured from the conductor film used for each of the through electrodes 106 and 116. At this time, the through electrodes 106 and 116, the rear face lines 126, 136, 166, 176, and 416, and the vias 146 and 156 can be formed from a conductor film in one layer. The via 146 is connected to the lower electrode 113 through the opening 446, and the via 156 is connected to the upper electrode 133 through the opening 155. Further, the through electrode 106 is connected to the via 146 through the rear face line 126 and connected also to the rear face line 416 and is connected to the bump electrode 107 through the rear face line 166. The through electrode 116 is connected to the via 156 through the rear face line 136 and is connected to the bump electrode 117 through the rear face line 176.

The insulating film 415 has a protective film 118 formed thereon. At this time, the protective film 118 can be positioned on the voids 131 and 141.

In this manner, in the fifth embodiment described hereinabove, the rear face line 416 configured by extending the conductor film used for the through electrode 106 provided on the semiconductor substrate 101 is used as a capacitive electrode. Consequently, the through electrode 106 and the rear face line 416 that is used as a capacitive electrode of the capacitive element 403 can be configured from the conductor of the same layer, and the capacitance of the capacitive element 403 per unit area can be increased, while increase of the manufacturing costs is suppressed.

### Sixth Embodiment

In the first embodiment described hereinabove, the capacitive element 103 connected to each of the through electrodes 106 and 116 is provided on the rear face of the semi-conductor substrate 101. In the sixth embodiment, a capacitive element connected to each of the through electrodes 106 and 116 is formed along an irregular surface of a side wall of a trench of the semiconductor substrate 101.

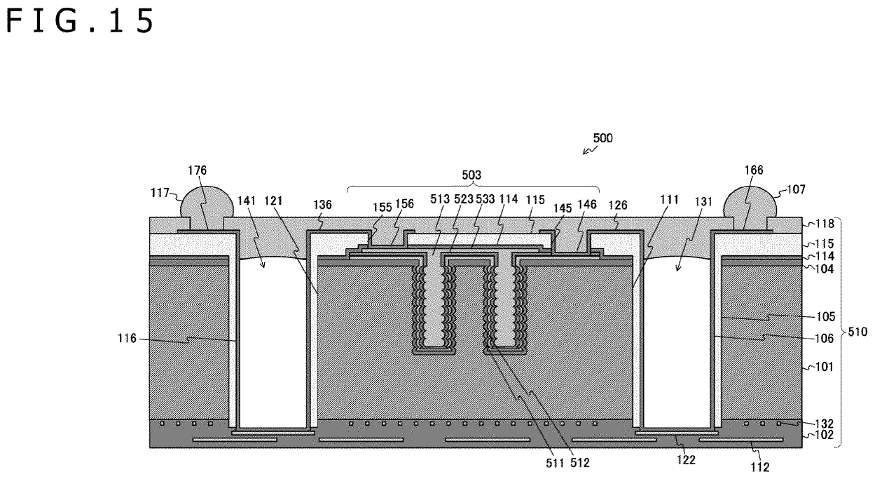

FIG. 15 is a cross sectional view depicting an example of a configuration of a semi-conductor device according to the sixth embodiment.

Referring to FIG. 15, a semiconductor device 500 includes a semiconductor chip 510 in place of the semiconductor chip 110 in the first embodiment described hereinabove. The semiconductor chip 510 includes a capacitive element 503 in place of the capacitive element 103 in the first embodiment described hereinabove. The configuration of the other part of the semiconductor device 500 of the sixth embodiment is similar to that of the semiconductor device 100 of the first embodiment described hereinabove.

The semiconductor substrate 101 has a trench 511 formed on the rear face side thereof. It is to be noted that, in order to facilitate formation of the capacitive element 503 in the trench 511, the trench 511 may have a tapered shape. The trench 511 has an irregular surface 512 formed on a side wall thereof. At this time, a side face roughness of the trench 511 may be greater than a side face roughness of each of the through-holes 111 and 121. In order to form the irregular surface 512 on the side wall of the trench 511, the trench 511 may be formed by repeating dry etching and deposition of the semiconductor substrate 101.

The capacitive element 503 includes a lower electrode 513, a dielectric film 523, and an upper electrode 533. The lower electrode 513 is formed over the side wall of the trench 511 to the rear face insulating film 104, and the upper electrode 533 is formed on the lower electrode 513 with the dielectric film 523 interposed therebetween. At this time, the lower electrode 513, dielectric film 523 and upper electrode 533 have formed thereon an irregular-surface structure on which the irregular surface 512 of the side wall of the trench 511 is reflected. The capacitive element 503 has an insulating film 115 formed thereon with a sealing film 114 interposed therebetween.

The insulating film 115, the sealing film 114, and the dielectric film 123 have an opening 145 formed therein such that the opening 145 exposes the lower electrode 513 therethrough. Further, the insulating film 115 and the sealing film 114 have an opening 155 formed thereon such that the opening 155 exposes the upper electrode 533 therethrough. The via 146 is connected to the lower electrode 513 through the opening 145, and the via 156 is connected to the upper electrode 533 through the opening 155.

In this manner, in the sixth embodiment described above, the capacitive element 503 connected to each of the through electrodes 106 and 116 is formed along the irregular surface 512 of the side wall of the trench 511 in the semiconductor substrate 101. Consequently, the capacitance per unit area of the capacitive element 503 can be increased, while reduction of the element formation region on the front face side of the semi-conductor substrate 101 is not necessary.

### 7. Seventh Embodiment

In the first embodiment described hereinabove, the capacitive element 103 connected to the through electrodes 106 and 116 is provided on the rear face of the semiconductor substrate 101. In the seventh embodiment, a capacitive element is formed along a side wall of a trench formed on the rear face side of the semiconductor substrate 101 in which a through electrode is provided, a void is provided in the trench, and an insulating film that covers the capacitive element is formed on the void.

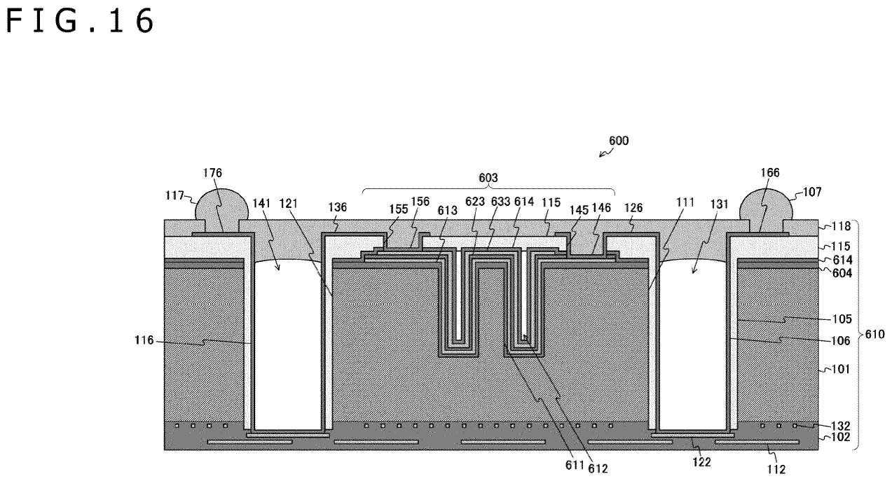

FIG. 16 is a cross sectional view depicting an example of a configuration of a semi-conductor device according to the seventh embodiment.

Referring to FIG. 16, the semiconductor device 600 includes a semiconductor chip 610 in place of the semiconductor chip 110 in the first embodiment described hereinabove. The semiconductor chip 610 includes a capacitive element 603, a rear face insulating film 604, and a sealing film 614 in place of the capacitive element 103, the rear face insulating film 104, and the sealing film 114 in the first embodiment described hereinabove. The configuration of the other part of the semiconductor device 600 of the seventh embodiment is similar to that of the semiconductor device 100 of the first embodiment described hereinabove.

The semiconductor substrate 101 has a trench 611 formed on the rear face side thereof. It is to be noted that, in order to facilitate formation of a capacitive element 603 in the trench 611, the trench 611 may have a tapered shape. Further, an irregular surface may be formed on a side wall of the trench 611. The rear face insulating film 604 is formed over the side wall of the trench 611 to the rear face of the semiconductor substrate 101.

The capacitive element 603 includes a lower electrode 613, a dielectric film 623, and an upper electrode 633. The lower electrode 613 is formed over the rear face insulating film 604 in the trench 611 to the rear face insulating film 604 on the rear face of the semiconductor substrate 101, and the upper electrode 633 is formed on the lower electrode 613 with a dielectric film 623 interposed therebetween. At this time, the upper electrode 633 is formed in a form of a thin film in the trench 611. The sealing film 614 is formed so as to cover the capacitive element 603 over the upper electrode 633 in the trench 611 to the rear face insulating film 604 on the rear face of the semi-conductor substrate 101. At this time, the sealing film 614 is formed in a form of a thin film in the trench 611, and a void 612 is formed in the trench 611. An insulating film 115 is formed on the void 612.

The insulating film 115, the sealing film 614, and the dielectric film 623 have an opening 145 formed therein such that the opening 145 exposes the lower electrode 613 therethrough. Further, the insulating film 115 and the sealing film 614 have an opening 155 formed therein such that the opening 155 exposes the upper electrode 633 therethrough. The via 146 is connected to the lower electrode 613 through the opening 145, and the via 156 is connected to the upper electrode 633 through the opening 155.

In this manner, in the seventh embodiment described above, the capacitive element 603 is formed along the side wall of the trench 611 formed on the rear face side of the semiconductor substrate 101 in which the through electrodes 106 and 116 are provided, and the insulating film 115 is formed on the void 612 in the trench 611. Consequently, warping of the semiconductor substrate 101 arising from mechanical stress of the upper electrode 633 can be prevented, and while the capacitance per unit area of the capacitive element 603 is increased, degradation of mountability and degradation of reliability of the semiconductor chip 610 can be suppressed.

### 8. Eighth Embodiment

In the seventh embodiment described above, the capacitive element 603 is formed along the side wall of the trench 611 formed on the rear face side of the semiconductor substrate 101 in which the through electrodes 106 and 116 are provided, and the insulating film 115 is formed on the void 612 in the trench 611. In the eighth embodiment, a capacitive element 603 is formed along a side wall of a trench 611 formed on the rear face side of the semiconductor substrate 101 in which through electrodes 106 and 116 are provided, and a sealing film is formed on the void 612 in the trench 611.

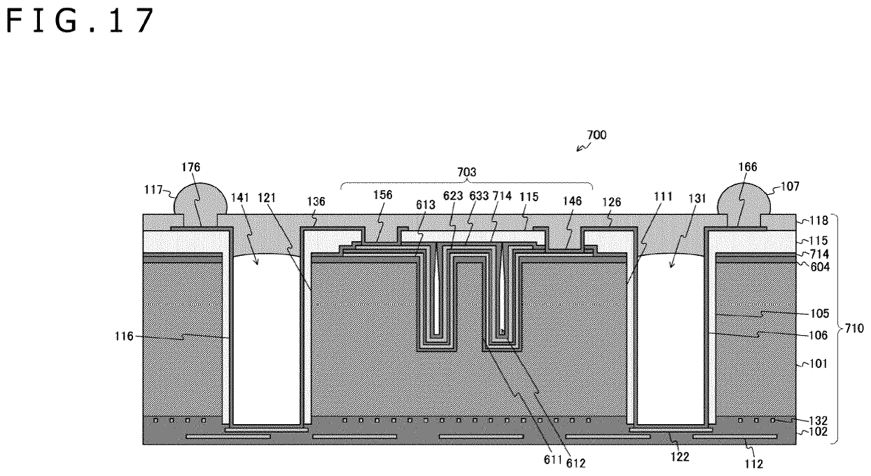

FIG. 17 is a cross sectional view depicting an example of a configuration of a semi-conductor device according to the eighth embodiment.

Referring to FIG. 17, a semiconductor device 700 includes a semiconductor chip 710 in place of the semiconductor chip 610 in the seventh embodiment described above. The semiconductor chip 710 includes a capacitive element 703 and a sealing film 714 in place of the capacitive element 603 and the sealing film 614 in the seventh embodiment described above. The configuration of the other part of the semiconductor device 700 of the eighth embodiment is similar to that of the semiconductor device 600 of the seventh embodiment described above.

The capacitive element 703 is sealed by the sealing film 714. At this time, the sealing film 714 is formed so as to cover the capacitive element 703 over the upper electrode 633 in the trench 611 to the rear face insulating film 604 on the rear face of the semi-conductor substrate 101. The sealing film 714 is formed in a form of a thin film so as to close an upper portion of the void 612 in the trench 611. A film thickness of the sealing film 714 can be made greater at a position thereof far from a bottom of the trench 611 than at a position thereof closer to the bottom of the trench 611. At this time, the void 612 may be formed, for example, in a shape of a spire.

In order to suppress warping of the semiconductor substrate 101 in which the trench 611 is formed, a compressive stress film may be used as the sealing film 714. For example, in a case where Si₃N₄ is used as a material of the sealing film 714, compressive stress can be applied on the basis of a film formation condition of Si₃N₄. This film formation condition is, for example, a gas flow rate upon film formation of Si₃N₄. At this time, the compression stress can be adjusted on the basis of an amount of nitrogen to be taken into the sealing film 714.

In this manner, in the eighth embodiment described above, the capacitive element 703 is formed along the side wall of the trench 611 formed on the rear face side of the semiconductor substrate 101 in which the through electrodes 106 and 116 are formed, and the sealing film 714 is formed so as to close an upper portion of the void 612 in the trench 611. At this time, compressive stress may be applied to the sealing film 714. This can prevent warping of the semiconductor substrate 101 that arises from mechanical stress of the upper electrode 633, and while the capacitance per unit area of the capacitive element 703 is increased, degradation of mountability and degradation of reliability of the semiconductor chip 710 can be suppressed.

It is to be noted that, in order to prevent warping of the semiconductor substrate 101 in which the trench 611 is formed, a film different from the sealing film 714 may be added.

### 9. Ninth Embodiment

In the first embodiment described hereinabove, the capacitive element 103 is formed on the rear face side of the semiconductor substrate 101 using the lower electrode 113 and the upper electrode 133 layered thereon with the dielectric film 123 interposed therebetween. In the ninth embodiment, a lower electrode provided on the rear face side of the semiconductor substrate 101 is patterned such that the lower electrode and an upper electrode also provided on the rear face side of the semiconductor substrate 101 have side faces opposed to each other.

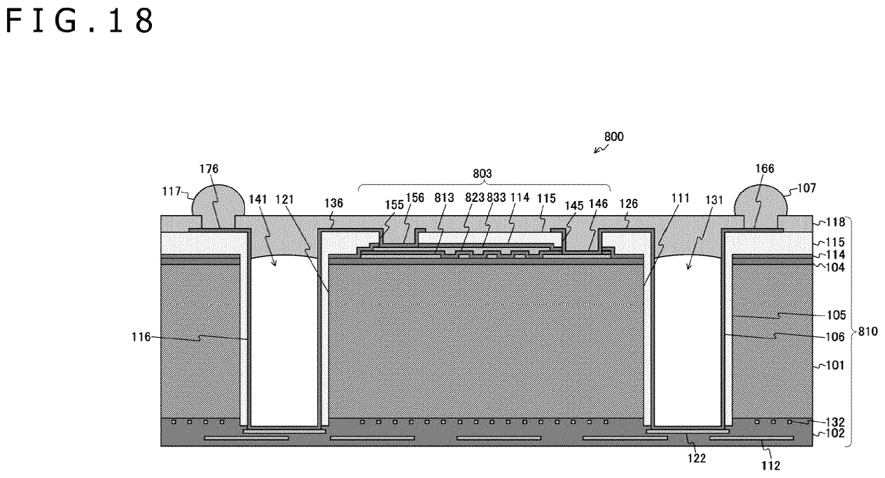

FIG. 18 is a cross sectional view depicting an example of a configuration of a semi-conductor device according to the ninth embodiment.

Referring to FIG. 18, a semiconductor device 800 includes a semiconductor chip 810 in place of the semiconductor chip 110 in the first embodiment described hereinabove. The semiconductor chip 810 includes a capacitive element 803 in place of the capacitive element 103 in the first embodiment described hereinabove. The configuration of the other part of the semiconductor device 800 of the ninth embodiment is similar to that of the semiconductor device 100 of the first embodiment described hereinabove.

The capacitive element 803 is formed on the rear face side of the semiconductor substrate 101 with a rear face insulating film 104 interposed therebetween. The capacitive element 803 includes a lower electrode 813, a dielectric film 823, and an upper electrode 833. The lower electrode 813 is formed on the rear face insulating film 104, and the upper electrode 833 is formed on the lower electrode 813 with the dielectric film 823 interposed therebetween.

The lower electrode 813 is patterned such that a side face thereof is exposed. The pattern of the lower electrode 813 may be, for example, of a comb shape or a spiral shape. At this time, the upper electrode 833 is layered on the lower electrode 813 so as to be opposed to a side face and an upper face of the lower electrode 813. The capacitive element 803 has an insulating film 115 formed thereon with a sealing film 114 interposed therebetween.

The insulating film 115, the sealing film 114, and the dielectric film 823 have an opening 145 formed therein such that the opening 145 exposes the lower electrode 813 therethrough. Further, the insulating film 115 and the sealing film 114 have an opening 155 formed therein such that the opening 155 exposes the upper electrode 833 therethrough. The via 146 is connected to the lower electrode 813 through the opening 145, and the via 156 is connected to the upper electrode 833 through the opening 155.

In this manner, in the ninth embodiment described above, the lower electrode 813 provided on the rear face side of the semiconductor substrate 101 is patterned such that the lower electrode 813 and the upper electrode 833 also provided on the rear face side of the semiconductor substrate 101 have side faces opposed to each other. Consequently, a capacitance can be provided between the side face of the lower electrode 613 and the side face of the upper electrode 833, and the capacitance of the capacitive element 803 can be increased without increasing the plane size of the capacitive element 803.

It is to be noted that, in the ninth embodiment described above, in order to expose the side face of the lower electrode 813, a hollow pattern is formed in the plane pattern. With the method of forming the hollow pattern in the plane pattern, an area of the upper face of the lower electrode 813 decreases, and the capacitance decreases in amount corresponding to the decreased area of the upper face of the lower electrode 813. Therefore, the lower electrode 813 may have an irregular surface formed on the upper face thereof. In order to form the irregular surface on the upper face of the lower electrode 813 without forming a hollow pattern for the lower electrode 813, the lower electrode 813 may be formed with a layered structure of conductor layers that are different in material from each other such that the conductor layer of the lowermost layer is used as an etching stopper.

### 10. Tenth Embodiment

In the first embodiment described hereinabove, the capacitive element 103 is formed on the rear face side of the semiconductor substrate 101 with use of the lower electrode 113 and the upper electrode 133 layered thereon with the dielectric film 123 interposed therebetween. In the tenth embodiment, a lower electrode provided on the rear face side of the semiconductor substrate 101 is patterned s as to have opposed side faces, and an upper electrode provided on the lower electrode is patterned so as to have opposed side faces.

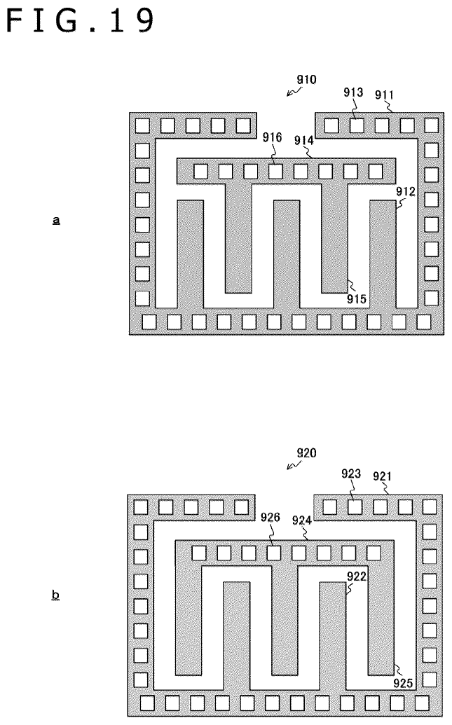

FIG. 19 depicts top plan views, each depicting an example of a configuration of a capacitive element according to the tenth embodiment. It is to be noted that Subfigure a of FIG. 19 is a top plan view depicting the lower electrode of the capacitive element, and Subfigure b of FIG. 19 is a top plan view depicting the upper electrode of the capacitive element.

Referring to FIG. 19, the capacitive element includes a lower electrode 910 and an upper electrode 920. As depicted in Subfigure a of FIG. 19, the lower electrode 910 includes base electrodes 911 and 914 and tab-shaped electrodes 912 and 915. The tab-shaped electrodes 912 are connected to the base electrode 911 so as to project from the base electrode 911. The tab-shaped electrodes 915 are connected to the base electrode 914 so as to project from the base electrode 914.

The base electrode 911 and the tab-shaped electrodes 912 are disposed to be spaced apart from the base electrode 914 and the tab-shaped electrodes 915. At this time, a side face of the tab-shaped electrode 912 and a side face of the tab-shaped electrode 915 can be disposed so as to be opposed to each other. At this time, the upper electrode 920 may configure, for example, a crossing comb-shaped electrode. Meanwhile, the base electrode 911 can be disposed so as to surround the base electrode 914 and the tab-shaped electrodes 912 and 915.

A contact 913 is formed in the base electrode 911, and a contact 916 is formed in the base electrode 914. The contact 913 may be formed in plural number at equal intervals in the base electrode 911, and the contact 916 may be formed in plural number at equal intervals in the base electrode 914.

Further, as depicted in Subfigure b of FIG. 19, the upper electrode 920 includes base electrodes 921 and 924 and tab-shaped electrodes 922 and 925. The tab-shaped electrodes 922 are connected to the base electrode 921 so as to project from the base electrode 921. The tab-shaped electrodes 925 are connected to the base electrode 924 so as to project from the base electrode 924.

The base electrode 921 and the tab-shaped electrodes 922 are disposed to be spaced apart from the base electrode 924 and the tab-shaped electrodes 925. At this time, a side face of the tab-shaped electrode 922 and a side face of the tab-shaped electrode 925 can be disposed so as to be opposed to each other. Here, the tab-shaped electrodes 922 can be disposed so as to be opposed to the tab-shaped electrodes 915 in the upward and downward direction, and the tab-shaped electrodes 925 can be disposed so as to be opposed to the tab-shaped electrodes 912 in the upward and downward direction. At this time, the upper electrode 920 may be configured, for example, as a crossing comb-shaped electrode. Further, the base electrode 921 can be disposed so as to surround the base electrode 924 and the tab-shaped electrodes 922 and 915.

The base electrode 921 has a contact 923 formed therein, and the base electrode 924 has a contact 926 formed therein. The contact 923 may be formed in plural number at equal intervals in the base electrode 921, and the contact 926 may be formed in plural number at equal intervals in the base electrode 924.

The base electrode 911 is connected to the base electrode 921 through the contacts 913 and 923. The base electrode 914 is connected to the base electrode 924 through the contacts 916 and 926. At this time, the tab-shaped electrodes 925 are stacked on the tab-shaped electrodes 912, and the tab-shaped electrodes 922 are stacked on the tab-shaped electrodes 915.

Here, the base electrodes 911 and 921 and the tab-shaped electrodes 912 and 922 are set to have the same polarity with each other. The base electrodes 914 and 924 and the tab-shaped electrodes 912 and 915 are set to have the same polarity with each other. The base electrodes 911 and 921 and the base electrodes 912 and 922 are formed to have polarities different from those of the base electrodes 914 and 924 and the tab-shaped electrodes 912 and 915.

At this time, between the tab-shaped electrodes 912 and 915, a capacitor is formed between upper and lower surfaces of them, and between the tab-shaped electrodes 915 and 922, a capacitor is formed between upper and lower faces of them. Between the tab-shaped electrodes 912 and 915, a capacitor is formed between the side faces of them, and between the tab-shaped electrodes 922 and 925, a capacitor is formed between the side faces of them.

In this manner, in the tenth embodiment described above, the lower electrode 910 and the upper electrode 920 are patterned such that a capacitor is formed between upper and lower faces of the lower electrode 910 and the upper electrode 920 and a capacitor is formed between side faces of the lower electrode 910 and the upper electrode 920. Consequently, the capacitance of the capacitive element can be increased without increasing the plane size of the capacitive element.

Further, the base electrode 911 is disposed so as to surround the base electrode 914 and the tab-shaped electrodes 912 and 915, and the base electrode 921 is disposed so as to surround the base electrode 924 and the tab-shaped electrodes 922 and 925. Further, the base electrodes 911 and 921 are connected to each other through the contacts 913 and 923. Consequently, the capacitors formed in the capacitive element can be shielded.

### 11. Eleventh Embodiment

In the first embodiment described hereinabove, the semiconductor chip 110 is formed such that the capacitive element 103 and the through electrodes 106 and 116 are connected to each other through lines configured by extending the conductor film used for each of the through electrodes 106 and 116 provided in the semiconductor substrate 101. In the eleventh embodiment, a semiconductor chip in which a solid-state imaging element is formed is stacked on a semiconductor chip 110 in which a capacitive element 103 connected to the through electrodes 106 and 116 is formed on the rear face side of the semiconductor substrate 101.

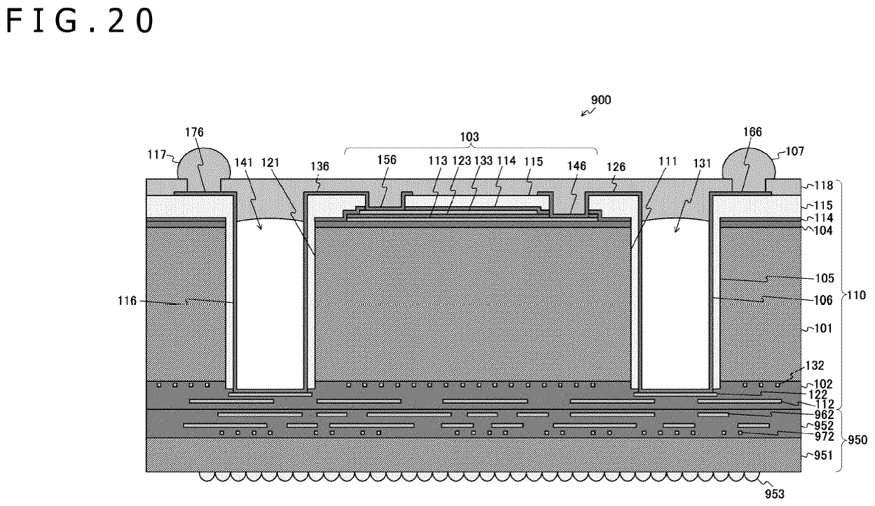

FIG. 20 is a cross sectional view depicting an example of a configuration of a semi-conductor device according to the eleventh embodiment.

Referring to FIG. 20, a semiconductor device 900 includes a semiconductor chip 950 that is additionally provided in the semiconductor device 100 of the first embodiment described hereinabove. The configuration of the other part of the semiconductor device 900 of the eleventh embodiment is similar to that of the semiconductor device 100 of the first embodiment described hereinabove.

The semiconductor chip 950 is stacked on the semiconductor chip 110. The semi-conductor chip 950 has a semiconductor element formed therein. The semiconductor element may be a solid-state imaging element such as a charge coupled device (CCD) or a complementary metal-oxide semiconductor (CMOS). The light to be received by the solid-state imaging element may be visible right or may be near infrared (NIR) light, short wavelength infrared light (SWIR), ultraviolet light, or an X-ray. The semi-conductor element may be a light receiving element such as a photodiode (PD), or a light emitting element such as a laser diode (LD), a light emitting diode (LED), or a vertical cavity surface emitting laser (VCSEL). It is to be noted that, in the following description, an example in which a back-illuminated solid-state imaging element is formed in the semiconductor chip 950 is described.

The semiconductor chip 950 includes a semiconductor layer 951 and a wiring layer 952. The semiconductor layer 951 has an imaging region and a non-imaging region provided therein. In the imaging region, pixels and pixel transistors arrayed in a matrix along a row direction and a column direction are disposed. In the non-imaging region, peripheral circuits that drive the pixel transistors and output signals read out from the pixels are provided.

On the rear face side of the semiconductor layer 951, an on-chip lens 953 is formed for each of the pixels. For a material of the on-chip lenses 953, a transparent resin such as, for example, acrylic or polycarbonate can be used. It is to be noted that a color filter may be provided for each pixel between the semiconductor layer 951 and the on-chip lens 953. At this time, the color filters can adopt, for example, a Bayer array.

The semiconductor layer 951 in which the semiconductor elements are formed has gate electrodes 972 formed thereon and has a wiring layer 952 formed thereon in such a manner as to cover the gate electrodes 972. The wiring layer 952 has lines 962 formed therein. The gate electrodes 972 and the lines 962 are embedded in an insulating film that insulates the wiring layer 952.

The wiring layer 952 is bonded to the wiring layer 102. At this time, the lines 962 of the wiring layer 952 can be electrically connected to the lines 112 of the wiring layer 102. In order to bond the wiring layer 952 to the wiring layer 102, direct bonding may be used. As the direct bonding, hybrid bonding may be used. In order to bond the lines 112 and 962 to each other, Cu-CU bonding may be used.

In this manner, in the eleventh embodiment described above, the semiconductor chip 950 in which the solid-state imaging element is formed is stacked on the semi-conductor chip 110 in which the capacitive element 103 connected to the through electrodes 106 and 116 is formed on the rear face side of the semiconductor substrate 101. Consequently, a noise resisting property of a signal transmission interface circuit used, for example, in the solid-state imaging element can be improved, and enhancement in performance in signal noise control can be achieved.

### 15. Example of Application to Mobile Body

The technology according to the present disclosure (present technology) can be applied to various products. For example, the technology according to the present disclosure may be implemented as a device incorporated in a mobile body of any type such as an automobile, an electric automobile, a hybrid electric automobile, a motorcycle, a bicycle, a personal mobility, an airplane, a drone, a ship, or a robot.

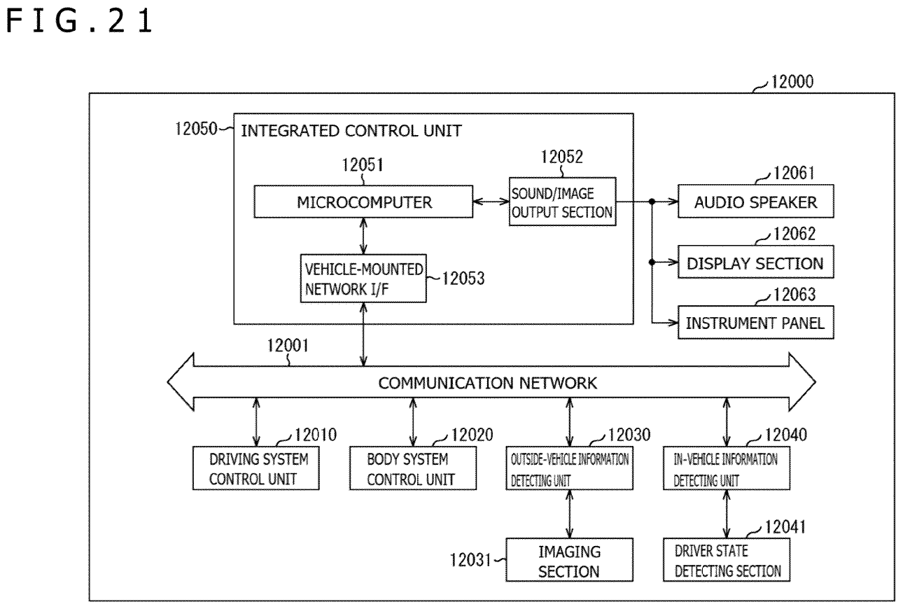

FIG. 21 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image or can output the electric signal as information about a measured distance. In addition, the light received by the imaging section 12031 may be visible light or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

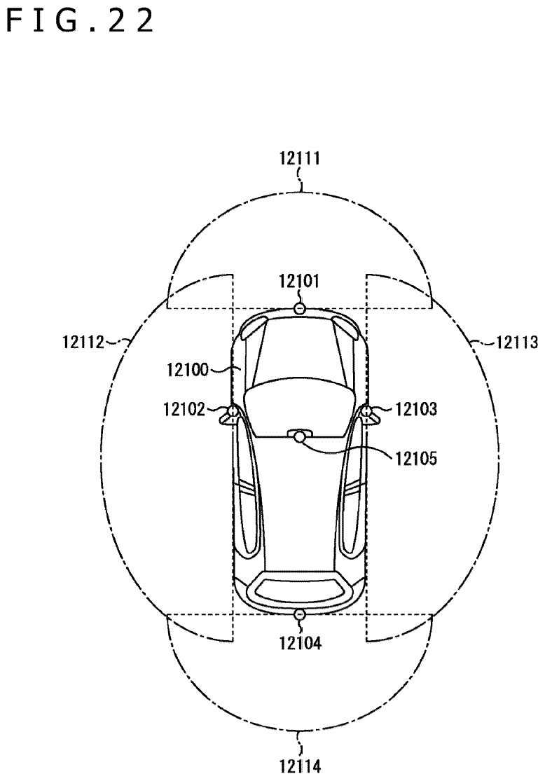

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062 and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applied has been described. The technology according to the present disclosure can be applied to any configuration in which as least any one of a semiconductor device, an optical device, a semiconductor package, and a circuit board is used from among the configurations described above. In particular, the semi-conductor devices 100 to 800 described above, and the like can be applied to at least any one of the configurations of the vehicle control system 12000. By applying the technology according to the present disclosure to the vehicle control system 12000, it becomes possible to implement at least part of the functions of the vehicle control while suppressing the influence of noise and to suppress increase of the mounting area.

It is to be noted that the embodiment described above indicates an example for embodying the present technology and matters in the embodiments and matters used to specify the technology in the claims individually have a corresponding relation. Similarly, the matters used to specify the technology in the claims and matters in the embodiment of the present technology denoted by the same names as those in the matters used to specify the technology in the claims individually have a corresponding relation. It is to be noted, however, that the present technology is not restricted to the embodiment and can be implemented by applying various modifications to the embodiment without departing from the gist of the present technology. Further, the advantageous effects described in the present specification are merely exemplary and are not restrictive, and other advantageous effects may be available.

Note that the present technology can also take the following configurations:
(1)

An electronic device including:
a substrate;
a through-hole penetrating the substrate;
a through electrode formed on a side wall of the through-hole;
a capacitive element formed on the substrate; and
a line that is formed by extending a conductor film used for the through electrode and is connected to the capacitive element.
(2)

The electronic device according to (1) above, in which
the substrate includes a semiconductor substrate in which a semiconductor element is formed or a wiring substrate in which a line is formed.
(3)

The electronic device according to one or more of (1) and (2) above, in which the capacitive element includes
an upper electrode,
a lower electrode, and
a dielectric film positioned between the upper electrode and the lower electrode,
the through electrode includes
a first through electrode, and
a second through electrode, and
the line includes
a first line that is formed by extending a conductor film used for the first through electrode and is connected to the upper electrode, and
a second line that is formed by extending a conductor film used for the second through electrode and is connected to the lower electrode.
(4)

The electronic device according to (3) above, in which
the upper electrode and the lower electrode each include at least any one of TiN, TaN, and WN.
(5)

The electronic device according to one or more of (3) and (4) above, in which the dielectric film includes at least any one of SiO₂, Si₃N₄, HfO₂, Al₂O₃, ZrO₂, and HfAlO.
(6)

The electronic device according to any one or more of (3) to (5) above, in which the dielectric film and the lower electrode have plane sizes substantially equal to each other, and the upper electrode has a plane size smaller than the plane sizes of the dielectric film and the lower electrode.
(7)

The electronic device according to (3) above, further including: a sealing film that is formed on the capacitive element and includes at least any one of Si₃N₄ and Al₂O₃.
(8)

The electronic device according to (7) above, further including:
a capacitive electrode formed on the upper electrode with the sealing film interposed therebetween and configured from the conductor film used for the second line.
(9)

The electronic device according to any one or more of (3) to (8) above, in which a parasitic capacitance between the substrate and the lower electrode is equal to or less than 1/10 the capacitance of the capacitive element.
(10)

The electronic device according to any one or more of (1) to (9) above, further including:
an insulating film formed on the capacitive element; and
at least any one of a line and an external connection terminal formed above the capacitive element with the insulating film interposed therebetween.
(11)

The electronic device according to any one or more of (1) to (10) above, further including:
a photosensitive insulating resin film that covers the through-hole.
(12)

The electronic device according to any one or more of (1) to (11) above, in which the substrate further includes a trench in which the capacitive element is formed.
(13)

The electronic device according to (12) above, further including:
a void provided in the trench.
(14)

The electronic device according to (13) above, further including:
an insulating film provided on the void.
(15)

The electronic device according to any one or more of (1) to (14) above, in which the capacitive element includes capacitive electrodes having polarities different from each other and having side faces opposed to each other.
(16)

The electronic device according to any one or more of (1) to (15) above, in which the line includes a plurality of vias connected to a capacitive electrode of the capacitive element.
(17)

The electronic device according to any one or more of (1) to (16) above, in which the capacitive element includes a plurality of capacitive elements having plane sizes different from each other.
(18)

The electronic device according to any one or more of (1) to (17) above, in which the capacitive element includes a plurality of upper electrodes that are disposed on the lower electrode and have plane sizes different from each other.
(19)

The electronic device according to any one or more of (1) to (18) above, further including:
a via connected to the lower electrode through a gap between the upper electrodes.
(20)

The electronic device according to any one or more of (1) to (19) above, in which the through electrode penetrates the capacitive element.
(21)

The electronic device according to any one or more of (1) to (20) above, further including:
a wiring layer that is formed on a face of the substrate on an opposite side to a formation face of the capacitive element and is connected to the through electrode; and a semiconductor chip connected to the wiring layer and having a solid-state imaging device formed therein.
(22)

An electronic device including:
a substrate;
a capacitive element formed on the substrate; and
a through electrode penetrating the substrate and the capacitive element.
(23)

The electronic device according to (22) above, further including:
a line that is formed by extending a conductor film used for the through electrode and is connected to the capacitive element.
(24)

An electronic device including:
a semiconductor substrate;
a wiring layer formed on a front face side of the semiconductor substrate;
a through electrode that penetrates the semiconductor substrate and is connected to the wiring layer;
a trench formed on a rear face side of the semiconductor substrate;
a capacitive element formed in the trench; and
a line that connects the through electrode and the capacitive element to each other.
(25)

The electronic device according to (24) above, in which
the line is configured by extending a conductor film used for the through electrode.
(26)

The electronic device according to one or more of (24) and (25) above, in which
the capacitive element is formed along a side wall of the trench, and
the trench has an irregular surface formed on the side wall thereof.
(27)

The electronic device according to any one or more of (24) to (26) above, further including:
a void provided in the trench.
(28)

A manufacturing method for an electronic device, including:
forming a capacitive element on a substrate;
forming a through-hole in the substrate on which the capacitive element is formed; and
forming a through electrode which is electrically connected to the capacitive element, on a side wall of the through-hole.
(29)

The manufacturing method for an electronic device according to (28) above, in which a conductor film used for the through electrode is extended and electrically connected to the capacitive element.
(30)

The manufacturing method for an electronic device according to one or more of (28) and (29) above, further including:
forming an insulating film that covers the side wall of the through-hole and the capacitive element; and
removing the insulating film from a bottom face of the through-hole and forming an opening in the insulating film on the capacitive element.
(31)

The manufacturing method for an electronic device according to any one or more of (28) to (30) above, further including:
forming a sealing film on the capacitive element formed on the substrate, in which the sealing film is used as an etching stopper when the opening is formed in the insulating film on the capacitive element.
(32)

An electronic device, comprising:
a substrate;
a first through-hole penetrating the substrate;
a capacitive element above the substrate; and
a first conductor film, wherein a first portion of the first conductor film traverses the substrate along a side wall of the first through-hole and a second portion of the first conductor film is in contact with the capacitive element.
(33)

The electronic device according to (32) above, wherein
the substrate includes one or both of a semiconductor substrate comprising a semi-conductor element and a wiring substrate comprising a wiring.
(34)

The electronic device according to one or more of (32) and (33) above, wherein
the capacitive element includes an upper electrode, a lower electrode, and a dielectric film between the upper electrode and the lower electrode,
the second portion of the first conductor film is in contact with the upper electrode, and
the electronic device further comprises a second conductor film and a second through-hole penetrating the substrate, wherein a first portion of the second conductor film traverses the substrate along a side wall of the second through-hole and a second portion of the second conductor film is in contact with the lower electrode.
(35)

The electronic device according to (34) above, wherein the upper electrode and the lower electrode each comprise one or more of TiN, TaN, and WN.
(36)

The electronic device according to one or more of (34) and (35) above, wherein the dielectric film comprises one or more of SiO₂, Si₃N₄, HfO₂, Al₂O₃, ZrO₂, and HfAlO.
(37)

The electronic device according to any one or more of (34) to (36) above, wherein the dielectric film and the lower electrode have plane sizes substantially equivalent to each other, and the upper electrode has a plane size smaller than the plane size of each of the dielectric film and the lower electrode.
(38)

The electronic device according to any one or more of (34) to (37) above, further comprising a sealing film on the capacitive element, the sealing film including one or more of Si₃N₄ and Al₂O₃.
(39)

The electronic device according to (38), wherein a third portion of the second conductor film is separated from the upper electrode by the sealing film.
(40)

The electronic device according to any one or more of (34) to (39) above, wherein a parasitic capacitance between the substrate and the lower electrode is equal to or less than one-tenth of a capacitance of the capacitive element.
(41)

The electronic device according to any one or more of (32) to (40) above, further comprising an insulating film on the capacitive element; and
one or more of a wiring and an external connection terminal above the capacitive element with the insulating film interposed therebetween.
(42)

The electronic device according to any one or more of (32) to (41) above, further comprising a photosensitive insulating resin film covering an opening of the first through-hole.
(43)

The electronic device according to any one or more of (32) to (42) above, wherein the substrate includes a trench in which the capacitive element is embedded.
(44)

The electronic device according to (43) above, further comprising a cavity provided in the trench.
(45)

The electronic device according to one or more of (43) and (44) above, further comprising an insulating film provided above the cavity.
(46)

The electronic device according to any one or more of (32) to (45) above, wherein the capacitive element includes capacitive electrodes having polarities different from each other and having side faces opposed to each other.
(47)

The electronic device according to any one or more of (32) to (46) above, wherein the first conductor film includes a plurality of vias connected to a capacitive electrode of the capacitive element.
(48)

The electronic device according to any one or more of (32) to (47) above, wherein the capacitive element includes a plurality of capacitive elements having plane sizes different from each other.
(49)

The electronic device according to any one or more of (32) to (49) above, wherein the capacitive element includes a plurality of upper electrodes above a lower electrode, wherein the plurality of upper electrodes have plane sizes different from each other.
(50)

The electronic device according to (49), further comprising a via connected to the lower electrode through a gap between the upper electrodes.
(51)

The electronic device according to any one or more of (32) to (50) above, wherein the first through-hole penetrates the capacitive element.
(52)

The electronic device according to any one or more of (32) to (51) above, further comprising:
a wiring layer on a bottom surface of the substrate and in contact with the first portion of the first conductor film, wherein the bottom surface of the substrate opposes a top surface of the substrate; and
a semiconductor chip connected to the wiring layer, the semiconductor chip comprising a solid-state imaging device.
(53)

An electronic device comprising:
a substrate;
a capacitive element above the substrate; and
a through electrode penetrating the substrate and the capacitive element.
(54)

The electronic device according to (53) above, wherein the through electrode comprises a first portion of a first conductor film and wherein a second portion of the first conductor film is in contact with the capacitive element.
(55)

An electronic device comprising:
a semiconductor substrate;
a wiring layer on a front face side of the semiconductor substrate;
a through electrode that penetrates the semiconductor substrate and connects to the wiring layer;
a trench in a rear face of the semiconductor substrate;
a capacitive element embedded in the trench; and
a wiring that connects the through electrode to the capacitive element.
(56)

The electronic device according to (55) above, wherein the wiring comprises a conductor film, wherein the through electrode comprises a portion of the conductor film.
(57)

The electronic device according to one or more of (55) and (56) above, wherein at least a portion of the capacitive element extends along a side wall of the trench and the side wall of the trench comprises a textured surface.
(58)

The electronic device according to any one or more of (55) to (57) above, further comprising a cavity in the trench.
(59)

A method for manufacturing an electronic device, the method comprising:
forming a capacitive element on a substrate;
forming a through-hole in the substrate; and
forming a through electrode along a side wall of the through-hole, wherein the through electrode is electrically connected to the capacitive element.
(60)

The manufacturing method for an electronic device according to (59) above, wherein the through electrode comprises a portion of a conductor film, wherein the through electrode is electrically connected to the capacitive element.
(61)

The manufacturing method for an electronic device according to one or more of (60) and (61) above, further comprising:
forming an insulating film covering a side wall of the through-hole and the capacitive element; and
removing the insulating film from a bottom face of the through-hole to form an opening in the insulating film.
(62)

The manufacturing method for an electronic device according to (61) above, further comprising forming a sealing film on the capacitive element, wherein the portion of the insulating film is removed by etching the insulating film using the sealing film as an etching stopper.

### REFERENCE SIGNS LIST

100: Semiconductor device
110: Semiconductor chip
101: Semiconductor substrate
102: Wiring layer
112: Line
122: Pad electrode
132: Gate electrode
103: Capacitive element
113: Lower electrode
123: Dielectric film
133: Upper electrode
114: Sealing film
104: Rear face insulating film
105, 115: Insulating film
106, 116: Through electrode
107, 117: Bump electrode
111, 121: Through-hole
118: Protective film
131, 141: Void
126, 136, 166, 176: Rear face line
142, 145, 155: Opening
146, 156: Via

What is claimed is:

1. An electronic device, comprising:
a substrate;
a first through-hole penetrating the substrate;
a capacitive element above the substrate; and
a first conductor film, wherein a first portion of the first conductor film traverses the substrate along a side wall of the first through-hole and a second portion of the first conductor film is in contact with the capacitive element.

2. The electronic device according to claim 1, wherein
the substrate includes one or both of a semiconductor substrate comprising a semiconductor element and a wiring substrate comprising a wiring.

3. The electronic device according to claim 1, wherein
the capacitive element includes an upper electrode, a lower electrode, and a dielectric film between the upper electrode and the lower electrode,
the second portion of the first conductor film is in contact with the upper electrode, and
the electronic device further comprises a second conductor film and a second through-hole penetrating the substrate, wherein a first portion of the second conductor film traverses the substrate along a side wall of the second through-hole and a second portion of the second conductor film is in contact with the lower electrode.

4. The electronic device according to claim 3, wherein the upper electrode and the lower electrode each comprise one or more of TiN, TaN, and WN.

5. The electronic device according to claim 3, wherein the dielectric film comprises one or more of SiO₂, Si₃N₄, HfO₂, Al₂O₃, ZrO₂, and HfAlO.

6. The electronic device according to claim 3, wherein the dielectric film and the lower electrode have plane sizes substantially equivalent to each other, and the upper electrode has a plane size smaller than the plane size of each of the dielectric film and the lower electrode.

7. The electronic device according to claim 3, further comprising a sealing film on the capacitive element, the sealing film including one or more of Si₃N₄ and Al₂O₃.

18. The electronic device according to claim 7, wherein a third portion of the second conductor film is separated from the upper electrode by the sealing film.

9. The electronic device according to claim 3, wherein a parasitic capacitance between the substrate and the lower electrode is equal to or less than one-tenth of a capacitance of the capacitive element.

10. The electronic device according to claim 1, further comprising an insulating film on the capacitive element; and
one or more of a wiring and an external connection terminal above the capacitive element with the insulating film interposed therebetween.

11. The electronic device according to claim 1, further comprising a photosensitive insulating resin film covering an opening of the first through-hole.

12. The electronic device according to claim 1, wherein the substrate includes a trench in which the capacitive element is embedded.

13. The electronic device according to claim 12, further comprising a cavity provided in the trench.

14. The electronic device according to claim 13, further comprising an insulating film provided above the cavity.

15. The electronic device according to claim 1, wherein the capacitive element includes capacitive electrodes having polarities different from each other and having side faces opposed to each other.

16. The electronic device according to claim 1, wherein the first conductor film includes a plurality of vias connected to a capacitive electrode of the capacitive element.

17. The electronic device according to claim 1, wherein the capacitive element includes a plurality of capacitive elements having plane sizes different from each other.

18. The electronic device according to claim 1, wherein the capacitive element includes a plurality of upper electrodes above a lower electrode, wherein the plurality of upper electrodes have plane sizes different from each other.

19. The electronic device according to claim 18, further comprising a via connected to the lower electrode through a gap between the upper electrodes.

20. The electronic device according to claim 1, wherein the first through-hole penetrates the capacitive element.

21. The electronic device according to claim 1, further comprising:
a wiring layer on a bottom surface of the substrate and in contact with the first portion of the first conductor film, wherein the bottom surface of the substrate opposes a top surface of the substrate; and
a semiconductor chip connected to the wiring layer, the semiconductor chip comprising a solid-state imaging device.

22. An electronic device, comprising:
a substrate;
a capacitive element above the substrate; and
a through electrode penetrating the substrate and the capacitive element.

23. The electronic device according to claim 22, wherein the through electrode comprises a first portion of a first conductor film and wherein a second portion of the first conductor film is in contact with the capacitive element.

24. An electronic device, comprising:
a semiconductor substrate;
a wiring layer on a front face side of the semiconductor substrate;
a through electrode that penetrates the semiconductor substrate and connects to the wiring layer;
a trench in a rear face of the semiconductor substrate;
a capacitive element embedded in the trench; and
a wiring that connects the through electrode to the capacitive element.

25. The electronic device according to claim 24, wherein the wiring comprises a conductor film, wherein the through electrode comprises a portion of the conductor film.

26. The electronic device according to claim 24, wherein at least a portion of the capacitive element extends along a side wall of the trench and the side wall of the trench comprises a textured surface.

27. The electronic device according to claim 24, further comprising a cavity in the trench.

28. A method for manufacturing an electronic device, the method comprising:
forming a capacitive element on a substrate;
forming a through-hole in the substrate; and
forming a through electrode along a side wall of the through-hole, wherein the through electrode is electrically connected to the capacitive element.

29. The manufacturing method for an electronic device according to claim 28, wherein the through electrode comprises a portion of a conductor film, wherein the through electrode is electrically connected to the capacitive element.

30. The manufacturing method for an electronic device according to claim 28, further comprising:
forming an insulating film covering a side wall of the through-hole and the capacitive element; and
removing the insulating film from a bottom face of the through-hole to form an opening in the insulating film.

31. The manufacturing method for an electronic device according to claim 30, further comprising forming a sealing film on the capacitive element, wherein the portion of the insulating film is removed by etching the insulating film using the sealing film as an etching stopper.
